(19) United States
(12) Patent Application Publication
(10) Pub. No.: US 2026/0323349 A1
(43) Pub. Date: Oct. 15, 2026

(54) CHANNEL FEEDBACK FOR RADIO FREQUENCY SENSING

(71) Applicant: QUALCOMM Incorporated, San Diego, CA (US)

(72) Inventors: Marwen ZORGUI, San Diego, CA (US); Srinivas YERRAMALLI, San Diego, CA (US); Mohammed Ali Mohammed HIRZALLAH, San Diego, CA (US)

(21) Appl. No.: 19/179,992

(22) Filed: Apr. 15, 2025

(51) Int. Cl. H04W 24/10; H04W 28/06; H04W 64/00

(52) U.S. Cl. CPC H04W 24/10; H04W 28/06; H04W 64/00

(57) ABSTRACT

Aspects presented herein may enable a wireless device to provide a plurality of reference signal (RS)/channel measurements using an explicit feedback (e.g., a compressed representation) for radio frequency (RF) sensing and positioning, thereby improving the overall performance of RF sensing and positioning. For example, in one aspect of the present disclosure, a wireless device receives a configuration to compress and to report a set of RS measurements. The wireless device compresses, based on the configuration, the set of RS measurements using artificial intelligence (AI) or machine learning (ML) (AI/ML) to obtain a sequence of bits representing the set of RS measurements. The wireless device reports the sequence of bits representing the set of RS measurements.

### TECHNICAL FIELD

The present disclosure relates generally to communication systems, and more particularly, to wireless communication involving artificial intelligence (AI) or machine learning (ML) (AI/ML) positioning and sensing.

### INTRODUCTION

Wireless communication systems are widely deployed to provide various telecommunication services such as telephony, video, data, messaging, and broadcasts. Typical wireless communication systems may employ multiple-access technologies capable of supporting communication with multiple users by sharing available system resources. Examples of such multiple-access technologies include code division multiple access (CDMA) systems, time division multiple access (TDMA) systems, frequency division multiple access (FDMA) systems, orthogonal frequency division multiple access (OFDMA) systems, single-carrier frequency division multiple access (SC-FDMA) systems, and time division synchronous code division multiple access (TD-SCDMA) systems.

These multiple access technologies have been adopted in various telecommunication standards to provide a common protocol that enables different wireless devices to communicate on a municipal, national, regional, and even global level. An example telecommunication standard is 5G New Radio (NR). 5G NR is part of a continuous mobile broadband evolution promulgated by Third Generation Partnership Project (3GPP) to meet new requirements associated with latency, reliability, security, scalability (e.g., with Internet of Things (IoT)), and other requirements. 5G NR includes services associated with enhanced mobile broadband (eMBB), massive machine type communications (mMTC), and ultra-reliable low latency communications (URLLC). Some aspects of 5G NR may be based on the 4G Long Term Evolution (LTE) standard. There exists a need for further improvements in 5G NR technology. These improvements may also be applicable to other multi-access technologies and the telecommunication standards that employ these technologies.

Some telecommunication standards also provide positioning protocols and techniques that enable mobile network operators to provide high-accuracy location services to their subscribers. For example, 5G NR include various standards for network-based positioning that use signals and features of the 5G network to perform or improve the positioning of a device. There also exists a need for further improvements in these positioning protocols and techniques.

### BRIEF SUMMARY

The following presents a simplified summary of one or more aspects in order to provide a basic understanding of such aspects. This summary is not an extensive overview of all contemplated aspects. This summary neither identifies key or critical elements of all aspects nor delineates the scope of any or all aspects. Its sole purpose is to present some concepts of one or more aspects in a simplified form as a prelude to the more detailed description that is presented later.

In an aspect of the disclosure, a method, a computer-readable medium, and an apparatus are provided. The apparatus receives a configuration to compress and to report a set of reference signal (RS) measurements. The apparatus compresses, based on the configuration, the set of RS measurements using artificial intelligence (AI) or machine learning (ML) (AI/ML) to obtain a sequence of bits representing the set of RS measurements. The apparatus reports the sequence of bits representing the set of RS measurements.

In an aspect of the disclosure, a method, a computer-readable medium, and an apparatus are provided. The apparatus transmits, to a wireless device, a configuration to compress and to report a set of RS measurements using AI/ML. The apparatus receives, from the wireless device based on the configuration, a sequence of bits representing the set of RS measurements. The apparatus constructs the set of RS measurements from the sequence of bits or use the sequence of bits as an input for a processing algorithm.

To the accomplishment of the foregoing and related ends, the one or more aspects may include the features hereinafter fully described and particularly pointed out in the claims. The following description and the drawings set forth in detail certain illustrative features of the one or more aspects. These features are indicative, however, of but a few of the various ways in which the principles of various aspects may be employed.

### BRIEF DESCRIPTION OF THE DRAWINGS

FIG. 1 is a diagram illustrating an example of a wireless communications system and an access network.

FIG. 2A is a diagram illustrating an example of a first frame, in accordance with various aspects of the present disclosure.

FIG. 2B is a diagram illustrating an example of downlink (DL) channels within a subframe, in accordance with various aspects of the present disclosure.

FIG. 2C is a diagram illustrating an example of a second frame, in accordance with various aspects of the present disclosure.

FIG. 2D is a diagram illustrating an example of uplink (UL) channels within a subframe, in accordance with various aspects of the present disclosure.

FIG. 3 is a diagram illustrating an example of a base station and user equipment (UE) in an access network.

FIG. 4 is a diagram illustrating an example of a UE positioning based on reference signal measurements (which may also be referred to as “network-based positioning”) in accordance with various aspects of the present disclosure.

FIG. 5 is a diagram illustrating an example radio access technology (RAT)-dependent positioning in accordance with various aspects of the present disclosure.

FIG. 6A is a diagram illustrating an example of direct artificial intelligence (AI) or machine learning (ML) (AI/ML) positioning in accordance with various aspects of the present disclosure.

FIG. 6B is a diagram illustrating an example of AI/ML assisted positioning in accordance with various aspects of the present disclosure.

FIG. 7 is a diagram illustrating an example of UE-based positioning with a UE-side AI/ML model, direct AI/ML or AI/ML assisted positioning in accordance with various aspects of the present disclosure.

FIG. 8A is a diagram illustrating an example of UE-assisted/location management function (LMF)-based positioning with a UE-side AI/ML model, AI/ML assisted positioning in accordance with various aspects of the present disclosure.

FIG. 8B is a diagram illustrating an example of UE-assisted/LMF-based positioning with an LMF-side AI/ML model, direct AI/ML positioning in accordance with various aspects of the present disclosure.

FIG. 9A is a diagram illustrating an example of network node assisted positioning with a base station (gNB)-side AI/ML model, AI/ML assisted positioning in accordance with various aspects of the present disclosure.

FIG. 9B is a diagram illustrating an example of network node assisted positioning with LMF-side AI/ML model, direct AI/ML positioning in accordance with various aspects of the present disclosure.

FIG. 10A is a diagram illustrating an example of sensing with co-located sensing receiver and sensing transmitter in accordance with various aspects of the present disclosure.

FIG. 10B is a diagram illustrating an example of sensing with separated sensing receiver and sensing transmitter in accordance with various aspects of the present disclosure.

FIG. 11 is a diagram illustrating an example sensing data signal processing flow from analog-to-digital converter (ADC) samples to progressively higher-level data representations associated with an integrated sensing and communication (ISAC) in accordance with various aspects of the present disclosure.

FIG. 12A is a diagram illustrating an example use of AI/ML for the channel state information (CSI) feedback in accordance with various aspects of the present disclosure.

FIG. 12B is a diagram illustrating an example use of AI/ML for the CSI feedback in accordance with various aspects of the present disclosure.

FIG. 12C is a diagram illustrating an example use of AI/ML for the CSI feedback in accordance with various aspects of the present disclosure.

FIG. 13 is a diagram illustrating an example of sensing signal processing in accordance with various aspects of the present disclosure.

FIG. 14 is a communication flow illustrating an example of an enhanced channel feedback for radio frequency (RF) sensing in accordance with various aspects of the present disclosure.

FIG. 15 is a diagram illustrating an example of AI/ML encoder in accordance with various aspects of the present disclosure.

FIG. 16 is a flowchart of a method of wireless communication.

FIG. 17 is a flowchart of a method of wireless communication.

FIG. 18 is a diagram illustrating an example of a hardware implementation for an example apparatus and/or network entity.

FIG. 19 is a flowchart of a method of wireless communication.

FIG. 20 is a diagram illustrating an example of a hardware implementation for an example network entity.

### DETAILED DESCRIPTION

Aspects presented herein may improve the overall performance of radio frequency (RF) sensing and positioning by enabling wireless device(s) performing RF sensing and/or positioning to provide a plurality of RS/channel measurements using an explicit feedback. For example, in one aspect of the present disclosure, a receiving/reception (Rx) sensing node may be configured to measure multiple instances of the reference signal (RS)/channel to a transmitting/transmission (Tx) sensing node. For purposes of the present disclosure, an Rx sensing node may refer to the sensing node that receives the sensing signal, and an Tx sensing node may refer to the sensing node that transmits the sensing signal. Depending on implementations, the Rx sensing node and the Tx sensing node may be the same sensing node, or may be different sensing nodes. The Rx sensing node may perform pre-processing on the collection of RS/channel measurements (e.g., two-dimensional (2D) fast Fourier transform (FFT) to generate the Range-Doppler map). The Rx sensing node may compress its RS/channel measurements using an artificial intelligence (AI) or machine learning (ML) (AI/ML) encoder (e.g., an AI/ML model/functionality) to generate a sequence of bits representing the RS/channel measurements. Then, the Rx sensing node may report (e.g., transmit, indicate, etc.) the sequence of bits to a server (e.g., an entity that receives the sequence of bits). The server may be configured to reconstruct the channels using a corresponding/matching AI/ML decoder (e.g., an AI/ML model/functionality), or uses the feedback bits as an input for a processing algorithm (e.g., a sensing algorithm that fuses inputs from multiple sensing nodes and detects target(s). As such, aspects presented herein may significantly reduce the overhead of channel feedback.

The detailed description set forth below in connection with the drawings describes various configurations and does not represent the only configurations in which the concepts described herein may be practiced. The detailed description includes specific details for the purpose of providing a thorough understanding of various concepts. However, these concepts may be practiced without these specific details. In some instances, well known structures and components are shown in block diagram form in order to avoid obscuring such concepts.

Several aspects of telecommunication systems are presented with reference to various apparatus and methods. These apparatus and methods are described in the following detailed description and illustrated in the accompanying drawings by various blocks, components, circuits, processes, algorithms, etc. (collectively referred to as “elements”). These elements may be implemented using electronic hardware, computer software, or any combination thereof. Whether such elements are implemented as hardware or software depends upon the particular application and design constraints imposed on the overall system.

By way of example, an element, or any portion of an element, or any combination of elements may be implemented as a “processing system” that includes one or more processors. When multiple processors are implemented, the multiple processors may perform the functions individually or in combination. Examples of processors include microprocessors, microcontrollers, graphics processing units (GPUs), central processing units (CPUs), application processors, digital signal processors (DSPs), reduced instruction set computing (RISC) processors, systems on a chip (SoC), baseband processors, field programmable gate arrays (FPGAs), programmable logic devices (PLDs), state machines, gated logic, discrete hardware circuits, and other suitable hardware configured to perform the various functionality described throughout this disclosure. One or more processors in the processing system may execute software. Software, whether referred to as software, firmware, middleware, microcode, hardware description language, or otherwise, shall be construed broadly to mean instructions, instruction sets, code, code segments, program code, programs, subprograms, software components, applications, software applications, software packages, routines, subroutines, objects, executables, threads of execution, procedures, functions, or any combination thereof.

Accordingly, in one or more example aspects, implementations, and/or use cases, the functions described may be implemented in hardware, software, or any combination thereof. If implemented in software, the functions may be stored on or encoded as one or more instructions or code on a computer-readable medium. Computer-readable media includes computer storage media. Storage media may be any available media that can be accessed by a computer. By way of example, such computer-readable media can include a random-access memory (RAM), a read-only memory (ROM), an electrically erasable programmable ROM (EEPROM), optical disk storage, magnetic disk storage, other magnetic storage devices, combinations of the types of computer-readable media, or any other medium that can be used to store computer executable code in the form of instructions or data structures that can be accessed by a computer.

While aspects, implementations, and/or use cases are described in this application by illustration to some examples, additional or different aspects, implementations and/or use cases may come about in many different arrangements and scenarios. Aspects, implementations, and/or use cases described herein may be implemented across many differing platform types, devices, systems, shapes, sizes, and packaging arrangements. For example, aspects, implementations, and/or use cases may come about via integrated chip implementations and other non-module-component based devices (e.g., end-user devices, vehicles, communication devices, computing devices, industrial equipment, retail/purchasing devices, medical devices, artificial intelligence (AI)-enabled devices, etc.). While some examples may or may not be specifically directed to use cases or applications, a wide assortment of applicability of described examples may occur. Aspects, implementations, and/or use cases may range a spectrum from chip-level or modular components to non-modular, non-chip-level implementations and further to aggregate, distributed, or original equipment manufacturer (OEM) devices or systems incorporating one or more techniques herein. In some practical settings, devices incorporating described aspects and features may also include additional components and features for implementation and practice of claimed and described aspect. For example, transmission and reception of wireless signals necessarily includes a number of components for analog and digital purposes (e.g., hardware components including antenna, RF-chains, power amplifiers, modulators, buffer, processor(s), interleaver, adders/summers, etc.). Techniques described herein may be practiced in a wide variety of devices, chip-level components, systems, distributed arrangements, aggregated or disaggregated components, end-user devices, etc. of varying sizes, shapes, and constitution.

Deployment of communication systems, such as 5G NR systems, may be arranged in multiple manners with various components or constituent parts. In a 5G NR system, or network, a network node, a network entity, a mobility element of a network, a radio access network (RAN) node, a core network node, a network element, or a network equipment, such as a base station (BS), or one or more units (or one or more components) performing base station functionality, may be implemented in an aggregated or disaggregated architecture. For example, a BS (such as a Node B (NB), evolved NB (eNB), NR BS, 5G NB, access point (AP), a transmission reception point (TRP), or a cell, etc.) may be implemented as an aggregated base station (also known as a standalone BS or a monolithic BS) or a disaggregated base station.

An aggregated base station may be configured to utilize a radio protocol stack that is physically or logically integrated within a single RAN node. A disaggregated base station may be configured to utilize a protocol stack that is physically or logically distributed among two or more units (such as one or more central or centralized units (CUs), one or more distributed units (DUs), or one or more radio units (RUs)). In some aspects, a CU may be implemented within a RAN node, and one or more DUs may be co-located with the CU, or alternatively, may be geographically or virtually distributed throughout one or multiple other RAN nodes. The DUs may be implemented to communicate with one or more RUs. Each of the CU, DU and RU can be implemented as virtual units, i.e., a virtual central unit (VCU), a virtual distributed unit (VDU), or a virtual radio unit (VRU).

Base station operation or network design may consider aggregation characteristics of base station functionality. For example, disaggregated base stations may be utilized in an integrated access backhaul (IAB) network, an open radio access network (O-RAN (such as the network configuration sponsored by the O-RAN Alliance)), or a virtualized radio access network (vRAN, also known as a cloud radio access network (C-RAN)). Disaggregation may include distributing functionality across two or more units at various physical locations, as well as distributing functionality for at least one unit virtually, which can enable flexibility in network design. The various units of the disaggregated base station, or disaggregated RAN architecture, can be configured for wired or wireless communication with at least one other unit.

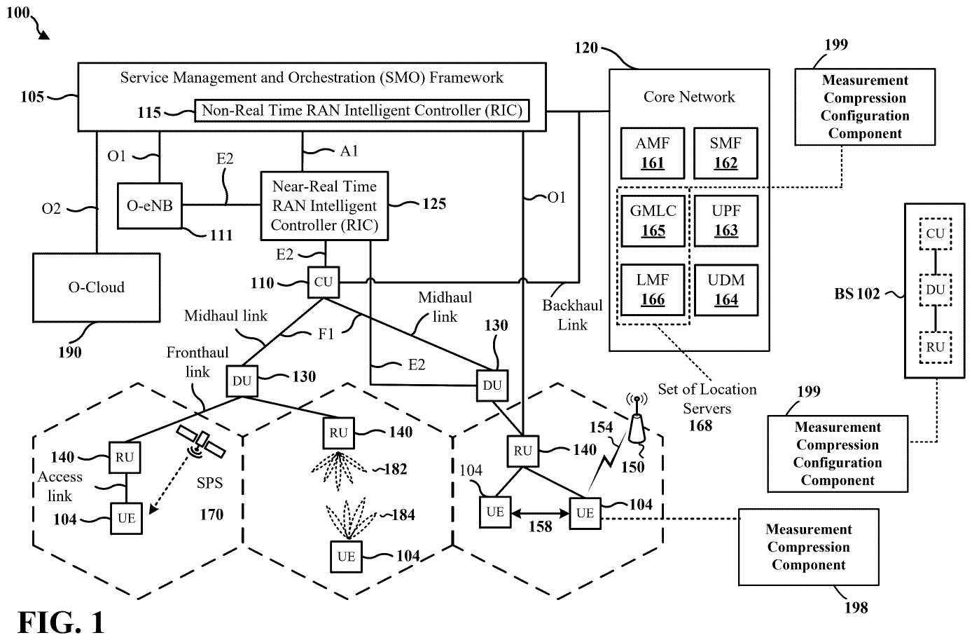

FIG. 1 is a diagram 100 illustrating an example of a wireless communications system and an access network. The illustrated wireless communications system includes a disaggregated base station architecture. The disaggregated base station architecture may include one or more CUs 110 that can communicate directly with a core network 120 via a backhaul link, or indirectly with the core network 120 through one or more disaggregated base station units (such as a Near-Real Time (Near-RT) RAN Intelligent Controller (RIC) 125 via an E2 link, or a Non-Real Time (Non-RT) RIC 115 associated with a Service Management and Orchestration (SMO) Framework 105, or both). A CU 110 may communicate with one or more DUs 130 via respective midhaul links, such as an F1 interface. The DUs 130 may communicate with one or more RUs 140 via respective fronthaul links. The RUs 140 may communicate with respective UEs 104 via one or more radio frequency (RF) access links. In some implementations, the UE 104 may be simultaneously served by multiple RUs 140.

Each of the units, i.e., the CUS 110, the DUs 130, the RUs 140, as well as the Near-RT RICs 125, the Non-RT RICs 115, and the SMO Framework 105, may include one or more interfaces or be coupled to one or more interfaces configured to receive or to transmit signals, data, or information (collectively, signals) via a wired or wireless transmission medium. Each of the units, or an associated processor or controller providing instructions to the communication interfaces of the units, can be configured to communicate with one or more of the other units via the transmission medium. For example, the units can include a wired interface configured to receive or to transmit signals over a wired transmission medium to one or more of the other units. Additionally, the units can include a wireless interface, which may include a receiver, a transmitter, or a transceiver (such as an RF transceiver), configured to receive or to transmit signals, or both, over a wireless transmission medium to one or more of the other units.

In some aspects, the CU 110 may host one or more higher layer control functions. Such control functions can include radio resource control (RRC), packet data convergence protocol (PDCP), service data adaptation protocol (SDAP), or the like. Each control function can be implemented with an interface configured to communicate signals with other control functions hosted by the CU 110. The CU 110 may be configured to handle user plane functionality (i.e., Central Unit-User Plane (CU-UP)), control plane functionality (i.e., Central Unit-Control Plane (CU-CP)), or a combination thereof. In some implementations, the CU 110 can be logically split into one or more CU-UP units and one or more CU-CP units. The CU-UP unit can communicate bidirectionally with the CU-CP unit via an interface, such as an E1 interface when implemented in an O-RAN configuration. The CU 110 can be implemented to communicate with the DU 130, as necessary, for network control and signaling.

The DU 130 may correspond to a logical unit that includes one or more base station functions to control the operation of one or more RUs 140. In some aspects, the DU 130 may host one or more of a radio link control (RLC) layer, a medium access control (MAC) layer, and one or more high physical (PHY) layers (such as modules for forward error correction (FEC) encoding and decoding, scrambling, modulation, demodulation, or the like) depending, at least in part, on a functional split, such as those defined by 3GPP. In some aspects, the DU 130 may further host one or more low PHY layers. Each layer (or module) can be implemented with an interface configured to communicate signals with other layers (and modules) hosted by the DU 130, or with the control functions hosted by the CU 110.

Lower-layer functionality can be implemented by one or more RUs 140. In some deployments, an RU 140, controlled by a DU 130, may correspond to a logical node that hosts RF processing functions, or low-PHY layer functions (such as performing fast Fourier transform (FFT), inverse FFT (iFFT), digital beamforming, physical random access channel (PRACH) extraction and filtering, or the like), or both, based at least in part on the functional split, such as a lower layer functional split. In such an architecture, the RU(s) 140 can be implemented to handle over the air (OTA) communication with one or more UEs 104. In some implementations, real-time and non-real-time aspects of control and user plane communication with the RU(s) 140 can be controlled by the corresponding DU 130. In some scenarios, this configuration can enable the DU(s) 130 and the CU 110 to be implemented in a cloud-based RAN architecture, such as a vRAN architecture.

The SMO Framework 105 may be configured to support RAN deployment and provisioning of non-virtualized and virtualized network elements. For non-virtualized network elements, the SMO Framework 105 may be configured to support the deployment of dedicated physical resources for RAN coverage requirements that may be managed via an operations and maintenance interface (such as an O1 interface). For virtualized network elements, the SMO Framework 105 may be configured to interact with a cloud computing platform (such as an open cloud (O-Cloud) 190) to perform network element life cycle management (such as to instantiate virtualized network elements) via a cloud computing platform interface (such as an O2 interface). Such virtualized network elements can include, but are not limited to, CUs 110, DUs 130, RUs 140 and Near-RT RICs 125. In some implementations, the SMO Framework 105 can communicate with a hardware aspect of a 4G RAN, such as an open eNB (O-eNB) 111, via an O1 interface. Additionally, in some implementations, the SMO Framework 105 can communicate directly with one or more RUs 140 via an O1 interface. The SMO Framework 105 also may include a Non-RT RIC 115 configured to support functionality of the SMO Framework 105.

The Non-RT RIC 115 may be configured to include a logical function that enables non-real-time control and optimization of RAN elements and resources, artificial intelligence (AI)/machine learning (ML) (AI/ML) workflows including model training and updates, or policy-based guidance of applications/features in the Near-RT RIC 125. The Non-RT RIC 115 may be coupled to or communicate with (such as via an A1 interface) the Near-RT RIC 125. The Near-RT RIC 125 may be configured to include a logical function that enables near-real-time control and optimization of RAN elements and resources via dataset collection and actions over an interface (such as via an E2 interface) connecting one or more CUs 110, one or more DUs 130, or both, as well as an O-eNB, with the Near-RT RIC 125.

In some implementations, to generate AI/ML models to be deployed in the Near-RT RIC 125, the Non-RT RIC 115 may receive parameters or external enrichment information from external servers. Such information may be utilized by the Near-RT RIC 125 and may be received at the SMO Framework 105 or the Non-RT RIC 115 from non-network data sources or from network functions. In some examples, the Non-RT RIC 115 or the Near-RT RIC 125 may be configured to tune RAN behavior or performance. For example, the Non-RT RIC 115 may monitor long-term trends and patterns for performance and employ AI/ML models to perform corrective actions through the SMO Framework 105 (such as reconfiguration via O1) or via creation of RAN management policies (such as A1 policies).

At least one of the CU 110, the DU 130, and the RU 140 may be referred to as a base station 102. Accordingly, a base station 102 may include one or more of the CU 110, the DU 130, and the RU 140 (each component indicated with dotted lines to signify that each component may or may not be included in the base station 102). The base station 102 provides an access point to the core network 120 for a UE 104. The base station 102 may include macrocells (high power cellular base station) and/or small cells (low power cellular base station). The small cells include femtocells, picocells, and microcells. A network that includes both small cell and macrocells may be known as a heterogeneous network. A heterogeneous network may also include Home Evolved Node Bs (eNBs) (HeNBs), which may provide service to a restricted group known as a closed subscriber group (CSG). The communication links between the RUs 140 and the UEs 104 may include uplink (UL) (also referred to as reverse link) transmissions from a UE 104 to an RU 140 and/or downlink (DL) (also referred to as forward link) transmissions from an RU 140 to a UE 104. The communication links may use multiple-input and multiple-output (MIMO) antenna technology, including spatial multiplexing, beamforming, and/or transmit diversity. The communication links may be through one or more carriers. The base station 102/UEs 104 may use spectrum up to Y MHz (e.g., 5, 10, 15, 20, 100, 400, etc. MHz) bandwidth per carrier allocated in a carrier aggregation of up to a total of Yx MHz (x component carriers) used for transmission in each direction. The carriers may or may not be adjacent to each other. Allocation of carriers may be asymmetric with respect to DL and UL (e.g., more or fewer carriers may be allocated for DL than for UL). The component carriers may include a primary component carrier and one or more secondary component carriers. A primary component carrier may be referred to as a primary cell (PCell) and a secondary component carrier may be referred to as a secondary cell (SCell).

Certain UEs 104 may communicate with each other using device-to-device (D2D) communication link 158. The D2D communication link 158 may use the DL/UL wireless wide area network (WWAN) spectrum. The D2D communication link 158 may use one or more sidelink channels, such as a physical sidelink broadcast channel (PSBCH), a physical sidelink discovery channel (PSDCH), a physical sidelink shared channel (PSSCH), and a physical sidelink control channel (PSCCH). D2D communication may be through a variety of wireless D2D communications systems, such as for example, Bluetooth™ (Bluetooth is a trademark of the Bluetooth Special Interest Group (SIG)), Wi-Fi™ (Wi-Fi is a trademark of the Wi-Fi Alliance) based on the Institute of Electrical and Electronics Engineers (IEEE) 802.11 standard, LTE, or NR.

The wireless communications system may further include a Wi-Fi AP 150 in communication with UEs 104 (also referred to as Wi-Fi stations (STAs)) via communication link 154, e.g., in a 5 GHz unlicensed frequency spectrum or the like. When communicating in an unlicensed frequency spectrum, the UEs 104/AP 150 may perform a clear channel assessment (CCA) prior to communicating in order to determine whether the channel is available.

The electromagnetic spectrum is often subdivided, based on frequency/wavelength, into various classes, bands, channels, etc. In 5G NR, two initial operating bands have been identified as frequency range designations FR1 (410 MHz-7.125 GHZ) and FR2 (24.25 GHz-52.6 GHz). Although a portion of FR1 is greater than 6 GHz, FR1 is often referred to (interchangeably) as a “sub-6 GHz” band in various documents and articles. A similar nomenclature issue sometimes occurs with regard to FR2, which is often referred to (interchangeably) as a “millimeter wave” band in documents and articles, despite being different from the extremely high frequency (EHF) band (30 GHz-300 GHz) which is identified by the International Telecommunications Union (ITU) as a “millimeter wave” band.

The frequencies between FR1 and FR2 are often referred to as mid-band frequencies. Recent 5G NR studies have identified an operating band for these mid-band frequencies as frequency range designation FR3 (7.125 GHZ-24.25 GHZ). Frequency bands falling within FR3 may inherit FR1 characteristics and/or FR2 characteristics, and thus may effectively extend features of FR1 and/or FR2 into mid-band frequencies. In addition, higher frequency bands are currently being explored to extend 5G NR operation beyond 52.6 GHz. For example, three higher operating bands have been identified as frequency range designations FR2-2 (52.6 GHZ-71 GHz), FR4 (71 GHz-114.25 GHz), and FR5 (114.25 GHz-300 GHz). Each of these higher frequency bands falls within the EHF band.

With the above aspects in mind, unless specifically stated otherwise, the term “sub-6 GHz” or the like if used herein may broadly represent frequencies that may be less than 6 GHz, may be within FR1, or may include mid-band frequencies. Further, unless specifically stated otherwise, the term “millimeter wave” or the like if used herein may broadly represent frequencies that may include mid-band frequencies, may be within FR2, FR4, FR2-2, and/or FR5, or may be within the EHF band.

The base station 102 and the UE 104 may each include a plurality of antennas, such as antenna elements, antenna panels, and/or antenna arrays to facilitate beamforming. The base station 102 may transmit a beamformed signal 182 to the UE 104 in one or more transmit directions. The UE 104 may receive the beamformed signal from the base station 102 in one or more receive directions. The UE 104 may also transmit a beamformed signal 184 to the base station 102 in one or more transmit directions. The base station 102 may receive the beamformed signal from the UE 104 in one or more receive directions. The base station 102/UE 104 may perform beam training to determine the best receive and transmit directions for each of the base station 102/UE 104. The transmit and receive directions for the base station 102 may or may not be the same. The transmit and receive directions for the UE 104 may or may not be the same.

The base station 102 may include and/or be referred to as a gNB, Node B, eNB, an access point, a base transceiver station, a radio base station, a radio transceiver, a transceiver function, a basic service set (BSS), an extended service set (ESS), a TRP, network node, the network entity, network equipment, or some other suitable terminology. The base station 102 can be implemented as an integrated access and backhaul (IAB) node, a relay node, a sidelink node, an aggregated (monolithic) base station with a baseband unit (BBU) (including a CU and a DU) and an RU, or as a disaggregated base station including one or more of a CU, a DU, and/or an RU. The set of base stations, which may include disaggregated base stations and/or aggregated base stations, may be referred to as next generation (NG) RAN (NG-RAN).

The core network 120 may include an Access and Mobility Management Function (AMF) 161, a Session Management Function (SMF) 162, a User Plane Function (UPF) 163, a Unified Data Management (UDM) 164, one or more location servers 168, and other functional entities. The AMF 161 is the control node that processes the signaling between the UEs 104 and the core network 120. The AMF 161 supports registration management, connection management, mobility management, and other functions. The SMF 162 supports session management and other functions. The UPF 163 supports packet routing, packet forwarding, and other functions. The UDM 164 supports the generation of authentication and key agreement (AKA) credentials, user identification handling, access authorization, and subscription management. The one or more location servers 168 are illustrated as including a Gateway Mobile Location Center (GMLC) 165 and a Location Management Function (LMF) 166. However, generally, the one or more location servers 168 may include one or more location/positioning servers, which may include one or more of the GMLC 165, the LMF 166, a position determination entity (PDE), a serving mobile location center (SMLC), a mobile positioning center (MPC), or the like. The GMLC 165 and the LMF 166 support UE location services. The GMLC 165 provides an interface for clients/applications (e.g., emergency services) for accessing UE positioning information. The LMF 166 receives measurements and assistance information from the NG-RAN and the UE 104 via the AMF 161 to compute the position of the UE 104. The NG-RAN may utilize one or more positioning methods in order to determine the position of the UE 104. Positioning the UE 104 may involve signal measurements, a position estimate, and an optional velocity computation based on the measurements. The signal measurements may be made by the UE 104 and/or the base station 102 serving the UE 104. The signals measured may be based on one or more of a satellite positioning system (SPS) 170 (e.g., one or more of a Global Navigation Satellite System (GNSS), global position system (GPS), non-terrestrial network (NTN), or other satellite position/location system), LTE signals, wireless local area network (WLAN) signals, Bluetooth signals, a terrestrial beacon system (TBS), sensor-based information (e.g., barometric pressure sensor, motion sensor), NR enhanced cell ID (NR E-CID) methods, NR signals (e.g., multi-round trip time (Multi-RTT), DL angle-of-departure (DL-AoD), DL time difference of arrival (DL-TDOA), UL time difference of arrival (UL-TDOA), and UL angle-of-arrival (UL-AoA) positioning), and/or other systems/signals/sensors.

Examples of UEs 104 include a cellular phone, a smartphone, a session initiation protocol (SIP) phone, a laptop, a personal digital assistant (PDA), a satellite radio, a global positioning system, a multimedia device, a video device, a digital audio player (e.g., MP3 player), a camera, a game console, a tablet, a smart device, a wearable device, a vehicle, an electric meter, a gas pump, a large or small kitchen appliance, a healthcare device, an implant, a sensor/actuator, a display, or any other similar functioning device. Some of the UEs 104 may be referred to as IoT devices (e.g., parking meter, gas pump, toaster, vehicles, heart monitor, etc.). The UE 104 may also be referred to as a station, a mobile station, a subscriber station, a mobile unit, a subscriber unit, a wireless unit, a remote unit, a mobile device, a wireless device, a wireless communications device, a remote device, a mobile subscriber station, an access terminal, a mobile terminal, a wireless terminal, a remote terminal, a handset, a user agent, a mobile client, a client, or some other suitable terminology. In some scenarios, the term UE may also apply to one or more companion devices such as in a device constellation arrangement. One or more of these devices may collectively access the network and/or individually access the network.

Referring again to FIG. 1, in certain aspects, the UE 104 may have a measurement compression component 198 that may be configured to receive a configuration to compress and to report a set of reference signal (RS) measurements; compress, based on the configuration, the set of RS measurements using artificial intelligence (AI) or machine learning (ML) (AI/ML) to obtain a sequence of bits representing the set of RS measurements; and report the sequence of bits representing the set of RS measurements. In certain aspects, the base station 102 and/or the one or more location servers 168 may have a measurement compression configuration component 199 that may be configured to transmit, to a wireless device, a configuration to compress and to report a set of RS measurements using AI/ML; receive, from the wireless device based on the configuration, a sequence of bits representing the set of RS measurements; and construct the set of RS measurements from the sequence of bits or use the sequence of bits as an input for a processing algorithm.

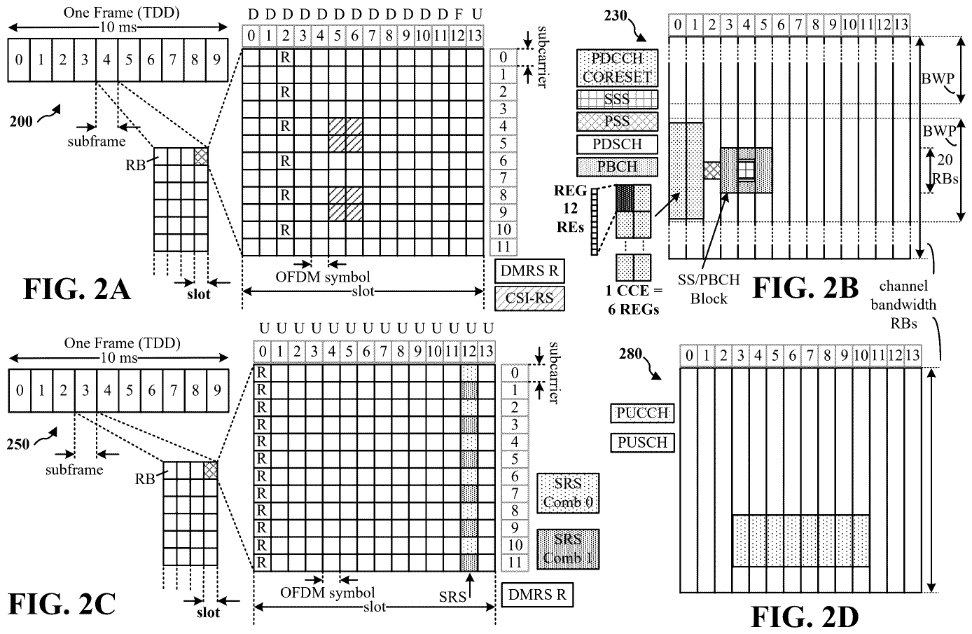

FIG. 2A is a diagram 200 illustrating an example of a first subframe within a 5G NR frame structure. FIG. 2B is a diagram 230 illustrating an example of DL channels within a 5G NR subframe. FIG. 2C is a diagram 250 illustrating an example of a second subframe within a 5G NR frame structure. FIG. 2D is a diagram 280 illustrating an example of UL channels within a 5G NR subframe. The 5G NR frame structure may be frequency division duplexed (FDD) in which for a particular set of subcarriers (carrier system bandwidth), subframes within the set of subcarriers are dedicated for either DL or UL, or may be time division duplexed (TDD) in which for a particular set of subcarriers (carrier system bandwidth), subframes within the set of subcarriers are dedicated for both DL and UL. In the examples provided by FIGS. 2A, 2C, the 5G NR frame structure is assumed to be TDD, with subframe 4 being configured with slot format 28 (with mostly DL), where D is DL, U is UL, and F is flexible for use between DL/UL, and subframe 3 being configured with slot format 1 (with all UL). While subframes 3, 4 are shown with slot formats 1, 28, respectively, any particular subframe may be configured with any of the various available slot formats 0-61. Slot formats 0, 1 are all DL, UL, respectively. Other slot formats 2-61 include a mix of DL, UL, and flexible symbols. UEs are configured with the slot format (dynamically through DL control information (DCI), or semi-statically/statically through radio resource control (RRC) signaling) through a received slot format indicator (SFI). Note that the description infra applies also to a 5G NR frame structure that is TDD.

FIGS. 2A-2D illustrate a frame structure, and the aspects of the present disclosure may be applicable to other wireless communication technologies, which may have a different frame structure and/or different channels. A frame (10 ms) may be divided into 10 equally sized subframes (1 ms). Each subframe may include one or more time slots. Subframes may also include mini-slots, which may include 7, 4, or 2 symbols. Each slot may include 14 or 12 symbols, depending on whether the cyclic prefix (CP) is normal or extended. For normal CP, each slot may include 14 symbols, and for extended CP, each slot may include 12 symbols. The symbols on DL may be CP orthogonal frequency division multiplexing (OFDM) (CP-OFDM) symbols. The symbols on UL may be CP-OFDM symbols (for high throughput scenarios) or discrete Fourier transform (DFT) spread OFDM (DFT-s-OFDM) symbols (for power limited scenarios; limited to a single stream transmission). The number of slots within a subframe is based on the CP and the numerology. The numerology defines the subcarrier spacing (SCS) (see Table 1). The symbol length/duration may scale with 1/SCS.

TABLE 1
Numerology, SCS, and CP

| | SCS | |
|---|---|---|
| μ | Δf = 2^{μ} · 15[kHz] | Cyclic prefix |
| 0 | 15 | Normal |
| 1 | 30 | Normal |
| 2 | 60 | Normal, Extended |
| 3 | 120 | Normal |
| 4 | 240 | Normal |
| 5 | 480 | Normal |
| 6 | 960 | Normal |

For normal CP (14 symbols/slot), different numerologies μ 0 to 4 allow for 1, 2, 4, 8, and 16 slots, respectively, per subframe. For extended CP, the numerology 2 allows for 4 slots per subframe. Accordingly, for normal CP and numerology μ, there are 14 symbols/slot and 2^{μ} slots/subframe. The subcarrier spacing may be equal to 2^{μ}*15 kHz, where μ is the numerology 0 to 4. As such, the numerology μ=0 has a subcarrier spacing of 15 kHz and the numerology μ=4 has a subcarrier spacing of 240 kHz. The symbol length/duration is inversely related to the subcarrier spacing. FIGS. 2A-2D provide an example of normal CP with 14 symbols per slot and numerology μ=2 with 4 slots per subframe. The slot duration is 0.25 ms, the subcarrier spacing is 60 kHz, and the symbol duration is approximately 16.67 μs. Within a set of frames, there may be one or more different bandwidth parts (BWPs) (see FIG. 2B) that are frequency division multiplexed. Each BWP may have a particular numerology and CP (normal or extended).

A resource grid may be used to represent the frame structure. Each time slot includes a resource block (RB) (also referred to as physical RBs (PRBs)) that extends 12 consecutive subcarriers. The resource grid is divided into multiple resource elements (REs). The number of bits carried by each RE depends on the modulation scheme.

As illustrated in FIG. 2A, some of the REs carry reference (pilot) signals (RS) for the UE. The RS may include demodulation RS (DM-RS) (indicated as R for one particular configuration, but other DM-RS configurations are possible) and channel state information reference signals (CSI-RS) for channel estimation at the UE. The RS may also include beam measurement RS (BRS), beam refinement RS (BRRS), and phase tracking RS (PT-RS).

FIG. 2B illustrates an example of various DL channels within a subframe of a frame. The physical downlink control channel (PDCCH) carries DCI within one or more control channel elements (CCEs) (e.g., 1, 2, 4, 8, or 16 CCEs), each CCE including six RE groups (REGs), each REG including 12 consecutive REs in an OFDM symbol of an RB. A PDCCH within one BWP may be referred to as a control resource set (CORESET). A UE is configured to monitor PDCCH candidates in a PDCCH search space (e.g., common search space, UE-specific search space) during PDCCH monitoring occasions on the CORESET, where the PDCCH candidates have different DCI formats and different aggregation levels. Additional BWPs may be located at greater and/or lower frequencies across the channel bandwidth. A primary synchronization signal (PSS) may be within symbol 2 of particular subframes of a frame. The PSS is used by a UE 104 to determine subframe/symbol timing and a physical layer identity. A secondary synchronization signal (SSS) may be within symbol 4 of particular subframes of a frame. The SSS is used by a UE to determine a physical layer cell identity group number and radio frame timing. Based on the physical layer identity and the physical layer cell identity group number, the UE can determine a physical cell identifier (PCI). Based on the PCI, the UE can determine the locations of the DM-RS. The physical broadcast channel (PBCH), which carries a master information block (MIB), may be logically grouped with the PSS and SSS to form a synchronization signal (SS)/PBCH block (also referred to as SS block (SSB)). The MIB provides a number of RBs in the system bandwidth and a system frame number (SFN). The physical downlink shared channel (PDSCH) carries user data, broadcast system information not transmitted through the PBCH such as system information blocks (SIBs), and paging messages.

As illustrated in FIG. 2C, some of the REs carry DM-RS (indicated as R for one particular configuration, but other DM-RS configurations are possible) for channel estimation at the base station. The UE may transmit DM-RS for the physical uplink control channel (PUCCH) and DM-RS for the physical uplink shared channel (PUSCH). The PUSCH DM-RS may be transmitted in the first one or two symbols of the PUSCH. The PUCCH DM-RS may be transmitted in different configurations depending on whether short or long PUCCHs are transmitted and depending on the particular PUCCH format used. The UE may transmit sounding reference signals (SRS). The SRS may be transmitted in the last symbol of a subframe. The SRS may have a comb structure, and a UE may transmit SRS on one of the combs. The SRS may be used by a base station for channel quality estimation to enable frequency-dependent scheduling on the UL.

FIG. 2D illustrates an example of various UL channels within a subframe of a frame. The PUCCH may be located as indicated in one configuration. The PUCCH carries uplink control information (UCI), such as scheduling requests, a channel quality indicator (CQI), a precoding matrix indicator (PMI), a rank indicator (RI), and hybrid automatic repeat request (HARQ) acknowledgment (ACK) (HARQ-ACK) feedback (i.e., one or more HARQ ACK bits indicating one or more ACK and/or negative ACK (NACK)). The PUSCH carries data, and may additionally be used to carry a buffer status report (BSR), a power headroom report (PHR), and/or UCI.

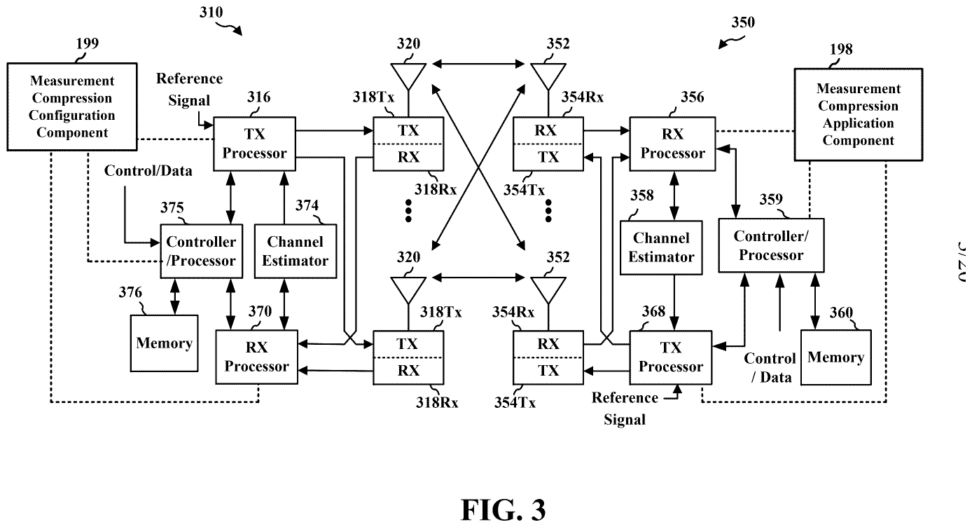

FIG. 3 is a block diagram of a base station 310 in communication with a UE 350 in an access network. In the DL, Internet protocol (IP) packets may be provided to a controller/processor 375. The controller/processor 375 implements layer 3 and layer 2 functionality. Layer 3 includes a radio resource control (RRC) layer, and layer 2 includes a service data adaptation protocol (SDAP) layer, a packet data convergence protocol (PDCP) layer, a radio link control (RLC) layer, and a medium access control (MAC) layer. The controller/processor 375 provides RRC layer functionality associated with broadcasting of system information (e.g., MIB, SIBs), RRC connection control (e.g., RRC connection paging, RRC connection establishment, RRC connection modification, and RRC connection release), inter radio access technology (RAT) mobility, and measurement configuration for UE measurement reporting; PDCP layer functionality associated with header compression/decompression, security (ciphering, deciphering, integrity protection, integrity verification), and handover support functions; RLC layer functionality associated with the transfer of upper layer packet data units (PDUs), error correction through ARQ, concatenation, segmentation, and reassembly of RLC service data units (SDUs), re-segmentation of RLC data PDUs, and reordering of RLC data PDUs; and MAC layer functionality associated with mapping between logical channels and transport channels, multiplexing of MAC SDUs onto transport blocks (TBs), demultiplexing of MAC SDUs from TBs, scheduling information reporting, error correction through HARQ, priority handling, and logical channel prioritization.

The transmit (TX) processor 316 and the receive (RX) processor 370 implement layer 1 functionality associated with various signal processing functions. Layer 1, which includes a physical (PHY) layer, may include error detection on the transport channels, forward error correction (FEC) coding/decoding of the transport channels, interleaving, rate matching, mapping onto physical channels, modulation/demodulation of physical channels, and MIMO antenna processing. The TX processor 316 handles mapping to signal constellations based on various modulation schemes (e.g., binary phase-shift keying (BPSK), quadrature phase-shift keying (QPSK), M-phase-shift keying (M-PSK), M-quadrature amplitude modulation (M-QAM)). The coded and modulated symbols may then be split into parallel streams. Each stream may then be mapped to an OFDM subcarrier, multiplexed with a reference signal (e.g., pilot) in the time and/or frequency domain, and then combined together using an Inverse Fast Fourier Transform (IFFT) to produce a physical channel carrying a time domain OFDM symbol stream. The OFDM stream is spatially precoded to produce multiple spatial streams. Channel estimates from a channel estimator 374 may be used to determine the coding and modulation scheme, as well as for spatial processing. The channel estimate may be derived from a reference signal and/or channel condition feedback transmitted by the UE 350. Each spatial stream may then be provided to a different antenna 320 via a separate transmitter 318Tx. Each transmitter 318Tx may modulate a radio frequency (RF) carrier with a respective spatial stream for transmission.

At the UE 350, each receiver 354Rx receives a signal through its respective antenna 352. Each receiver 354Rx recovers information modulated onto an RF carrier and provides the information to the receive (RX) processor 356. The TX processor 368 and the RX processor 356 implement layer 1 functionality associated with various signal processing functions. The RX processor 356 may perform spatial processing on the information to recover any spatial streams destined for the UE 350. If multiple spatial streams are destined for the UE 350, they may be combined by the RX processor 356 into a single OFDM symbol stream. The RX processor 356 then converts the OFDM symbol stream from the time-domain to the frequency domain using a Fast Fourier Transform (FFT). The frequency domain signal includes a separate OFDM symbol stream for each subcarrier of the OFDM signal. The symbols on each subcarrier, and the reference signal, are recovered and demodulated by determining the most likely signal constellation points transmitted by the base station 310. These soft decisions may be based on channel estimates computed by the channel estimator 358. The soft decisions are then decoded and deinterleaved to recover the data and control signals that were originally transmitted by the base station 310 on the physical channel. The data and control signals are then provided to the controller/processor 359, which implements layer 3 and layer 2 functionality.

The controller/processor 359 can be associated with at least one memory 360 that stores program codes and data. The at least one memory 360 may be referred to as a computer-readable medium. In the UL, the controller/processor 359 provides demultiplexing between transport and logical channels, packet reassembly, deciphering, header decompression, and control signal processing to recover IP packets. The controller/processor 359 is also responsible for error detection using an ACK and/or NACK protocol to support HARQ operations.

Similar to the functionality described in connection with the DL transmission by the base station 310, the controller/processor 359 provides RRC layer functionality associated with system information (e.g., MIB, SIBs) acquisition, RRC connections, and measurement reporting; PDCP layer functionality associated with header compression/decompression, and security (ciphering, deciphering, integrity protection, integrity verification); RLC layer functionality associated with the transfer of upper layer PDUs, error correction through ARQ, concatenation, segmentation, and reassembly of RLC SDUs, re-segmentation of RLC data PDUs, and reordering of RLC data PDUs; and MAC layer functionality associated with mapping between logical channels and transport channels, multiplexing of MAC SDUs onto TBs, demultiplexing of MAC SDUs from TBs, scheduling information reporting, error correction through HARQ, priority handling, and logical channel prioritization.

Channel estimates derived by a channel estimator 358 from a reference signal or feedback transmitted by the base station 310 may be used by the TX processor 368 to select the appropriate coding and modulation schemes, and to facilitate spatial processing. The spatial streams generated by the TX processor 368 may be provided to different antenna 352 via separate transmitters 354Tx. Each transmitter 354Tx may modulate an RF carrier with a respective spatial stream for transmission.

The UL transmission is processed at the base station 310 in a manner similar to that described in connection with the receiver function at the UE 350. Each receiver 318Rx receives a signal through its respective antenna 320. Each receiver 318Rx recovers information modulated onto an RF carrier and provides the information to a RX processor 370.

The controller/processor 375 can be associated with at least one memory 376 that stores program codes and data. The at least one memory 376 may be referred to as a computer-readable medium. In the UL, the controller/processor 375 provides demultiplexing between transport and logical channels, packet reassembly, deciphering, header decompression, control signal processing to recover IP packets. The controller/processor 375 is also responsible for error detection using an ACK and/or NACK protocol to support HARQ operations.

At least one of the TX processor 368, the RX processor 356, and the controller/processor 359 may be configured to perform aspects in connection with the measurement compression component 198 of FIG. 1.

At least one of the TX processor 316, the RX processor 370, and the controller/processor 375 may be configured to perform aspects in connection with the measurement compression configuration component 199 of FIG. 1.

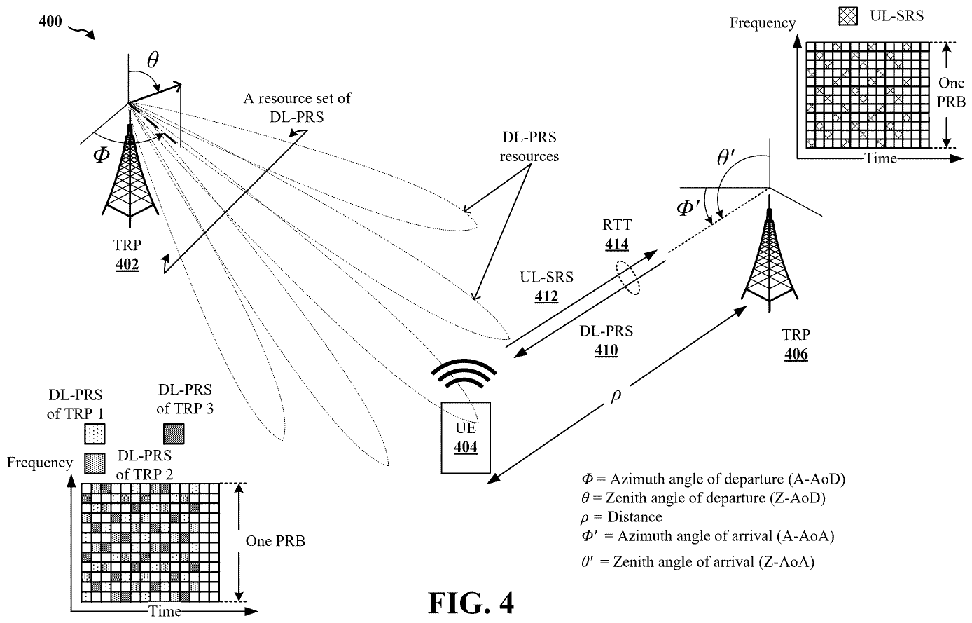

FIG. 4 is a diagram 400 illustrating an example of a UE positioning based on reference signal measurements (which may also be referred to as “network-based positioning”) in accordance with various aspects of the present disclosure. The UE 404 may transmit UL SRS 412 at time T_{SRS_TX} and receive DL positioning reference signals (PRS) (DL PRS) 410 at time T_{PRS_RX}. The TRP 406 may receive the UL SRS 412 at time T_{SRS_RX} and transmit the DL PRS 410 at time T_{PRS_TX}. The UE 404 may receive the DL PRS 410 before transmitting the UL SRS 412, or may transmit the UL SRS 412 before receiving the DL PRS 410. In both cases, a positioning server (e.g., location server(s) 168) or the UE 404 may determine the RTT 414 based on ∥T_{SRS_RX}−T_{PRS_TX}|−|T_{SRS_TX}−T_{PRS_RX}∥. Accordingly, multi-RTT positioning may make use of the UE Rx-Tx time difference measurements (i.e., |T_{SRS_TX}−T_{PRS_RX}|) and DL PRS reference signal received power (RSRP) (DL PRS-RSRP) of downlink signals received from multiple TRPs 402, 406 and measured by the UE 404, and the measured TRP Rx-Tx time difference measurements (i.e., |T_{SRS_RX}−T_{PRS_TX}|) and UL SRS-RSRP at multiple TRPs 402, 406 of uplink signals transmitted from UE 404. The UE 404 measures the UE Rx-Tx time difference measurements (and/or DL PRS-RSRP of the received signals) using assistance data received from the positioning server, and the TRPs 402, 406 measure the gNB Rx-Tx time difference measurements (and/or UL SRS-RSRP of the received signals) using assistance data received from the positioning server. The measurements may be used at the positioning server or the UE 404 to determine the RTT, which is used to estimate the location of the UE 404. Other methods are possible for determining the RTT, such as for example using DL-TDOA and/or UL-TDOA measurements.

PRSs may be defined for network-based positioning (e.g., NR positioning) to enable UEs to detect and measure more neighbor transmission and reception points (TRPs), where multiple configurations are supported to enable a variety of deployments (e.g., indoor, outdoor, sub-6, mmW, etc.). To support PRS beam operation, beam sweeping may also be configured for PRS. The UL positioning reference signal may be based on sounding reference signals (SRSs) with enhancements/adjustments for positioning purposes. In some examples, UL-PRS may be referred to as “SRS for positioning,” and a new Information Element (IE) may be configured for SRS for positioning in RRC signaling.

DL PRS-RSRP may be defined as the linear average over the power contributions (in [W]) of the resource elements of the antenna port(s) that carry DL PRS reference signals configured for RSRP measurements within the considered measurement frequency bandwidth. In some examples, for FR1, the reference point for the DL PRS-RSRP may be the antenna connector of the UE. For FR2, DL PRS-RSRP may be measured based on the combined signal from antenna elements corresponding to a given receiver branch. For FR1 and FR2, if receiver diversity is in use by the UE, the reported DL PRS-RSRP value may not be lower than the corresponding DL PRS-RSRP of any of the individual receiver branches. Similarly, UL SRS-RSRP may be defined as linear average of the power contributions (in [W]) of the resource elements carrying sounding reference signals (SRS). UL SRS-RSRP may be measured over the configured resource elements within the considered measurement frequency bandwidth in the configured measurement time occasions. In some examples, for FR1, the reference point for the UL SRS-RSRP may be the antenna connector of the base station (e.g., gNB). For FR2, UL SRS-RSRP may be measured based on the combined signal from antenna elements corresponding to a given receiver branch. For FR1 and FR2, if receiver diversity is in use by the base station, the reported UL SRS-RSRP value may not be lower than the corresponding UL SRS-RSRP of any of the individual receiver branches.

PRS-path RSRP (PRS-RSRPP) may be defined as the power of the linear average of the channel response at the i-th path delay of the resource elements that carry DL PRS signal configured for the measurement, where DL PRS-RSRPP for the 1st path delay is the power contribution corresponding to the first detected path in time. In some examples, PRS path Phase measurement may refer to the phase associated with an i-th path of the channel derived using a PRS resource.

DL-AoD positioning may make use of the measured DL PRS-RSRP of downlink signals received from multiple TRPs 402, 406 at the UE 404. The UE 404 measures the DL PRS-RSRP of the received signals using assistance data received from the positioning server, and the resulting measurements are used along with the azimuth angle of departure (A-AoD), the zenith angle of departure (Z-AoD), and other configuration information to locate the UE 404 in relation to the neighboring TRPs 402,406.

DL-TDOA positioning may make use of the DL reference signal time difference (RSTD) (and/or DL PRS-RSRP) of downlink signals received from multiple TRPs 402, 406 at the UE 404. The UE 404 measures the DL RSTD (and/or DL PRS-RSRP) of the received signals using assistance data received from the positioning server, and the resulting measurements are used along with other configuration information to locate the UE 404 in relation to the neighboring TRPs 402, 406.

UL-TDOA positioning may make use of the UL relative time of arrival (RTOA) (and/or UL SRS-RSRP) at multiple TRPs 402, 406 of uplink signals transmitted from UE 404. The TRPs 402, 406 measure the UL-RTOA (and/or UL SRS-RSRP) of the received signals using assistance data received from the positioning server, and the resulting measurements are used along with other configuration information to estimate the location of the UE 404.

UL-AoA positioning may make use of the measured azimuth angle of arrival (A-AoA) and zenith angle of arrival (Z-AoA) at multiple TRPs 402, 406 of uplink signals transmitted from the UE 404. The TRPs 402, 406 measure the A-AoA and the Z-AoA of the received signals using assistance data received from the positioning server, and the resulting measurements are used along with other configuration information to estimate the location of the UE 404. For purposes of the present disclosure, a positioning operation in which measurements are provided by a UE to a base station/positioning entity/server to be used in the computation of the UE's position may be described as “UE-assisted,” “UE-assisted positioning,” and/or “UE-assisted position calculation,” while a positioning operation in which a UE measures and computes its own position may be described as “UE-based,” “UE-based positioning,” and/or “UE-based position calculation.”

Additional positioning methods may be used for estimating the location of the UE 404, such as for example, UE-side UL-AoD and/or DL-AoA. Note that data/measurements from various technologies may be combined in various ways to increase accuracy, to determine and/or to enhance certainty, to supplement/complement measurements, and/or to substitute/provide for missing information.

Note that the terms “positioning reference signal” and “PRS” generally refer to specific reference signals that are used for positioning in NR and LTE systems. However, as used herein, the terms “positioning reference signal” and “PRS” may also refer to any type of reference signal that can be used for positioning, such as but not limited to, PRS as defined in LTE and NR, TRS, PTRS, CRS, CSI-RS, DMRS, PSS, SSS, SSB, SRS, UL-PRS, etc. In addition, the terms “positioning reference signal” and “PRS” may refer to downlink or uplink positioning reference signals, unless otherwise indicated by the context. To further distinguish the type of PRS, a downlink positioning reference signal may be referred to as a “DL PRS,” and an uplink positioning reference signal (e.g., an SRS-for-positioning, PTRS) may be referred to as an “UL-PRS.” In addition, for signals that may be transmitted in both the uplink and downlink (e.g., DMRS, PTRS), the signals may be prepended with “UL” or “DL” to distinguish the direction. For example, “UL-DMRS” may be differentiated from “DL-DMRS.” In addition, the term “location” and “position” may be used interchangeably throughout the specification, which may refer to a particular geographical or a relative place.

For purposes of the present disclosure, “UE Rx-Tx time difference” may be defined as TUE-RX-TUE-TX, where: TUE-RX is the UE received timing of downlink subframe #i from a Transmission Point (TP), defined by the first detected path in time. TUE-TX is the UE transmit timing of uplink subframe #j that is closest in time to the subframe #i received from the TP. Multiple DL PRS or CSI-RS for tracking resources, as instructed by higher layers, can be used to determine the start of one subframe of the first arrival path of the TP. For frequency range 1, the reference point for TUE-RX measurement may be the Rx antenna connector of the UE and the reference point for TUE-TX measurement may be the Tx antenna connector of the UE. For frequency range 2, the reference point for TUE-RX measurement may be the Rx antenna of the UE and the reference point for TUE-TX measurement may be the Tx antenna of the UE.

“DL reference signal time difference (DL RSTD)” is the DL relative timing difference between the Transmission Point (TP) j and the reference TP i, defined as T_{SubframeRxj}−T_{SubframeRxi}, where: T_{SubframeRxj} is the time when the UE receives the start of one subframe from TP j. T_{SubframeRxi} is the time when the UE receives the corresponding start of one subframe from TP i that is closest in time to the subframe received from TP j. Multiple DL PRS resources can be used to determine the start of one subframe from a TP. For frequency range 1, the reference point for the DL RSTD may be the antenna connector of the UE. For frequency range 2, the reference point for the DL RSTD may be the antenna of the UE.

“DL PRS reference signal received power (DL PRS-RSRP),” is defined as the linear average over the power contributions (in [W]) of the resource elements that carry DL PRS reference signals configured for RSRP measurements within the considered measurement frequency bandwidth. For frequency range 1, the reference point for the DL PRS-RSRP may be the antenna connector of the UE. For frequency range 2, DL PRS-RSRP may be measured based on the combined signal from antenna elements corresponding to a given receiver branch. For frequency range 1 and 2, if receiver diversity is in use by the UE, the reported DL PRS-RSRP value may not be lower than the corresponding DL PRS-RSRP of any of the individual receiver branches.

“DL PRS reference signal received path power (DL PRS-RSRPP),” is defined as the power of the linear average of the channel response at the i-th path delay of the resource elements that carry DL PRS signal configured for the measurement, where DL PRS-RSRPP for the 1st path delay is the power contribution corresponding to the first detected path in time. For frequency range 1, the reference point for the DL PRS-RSRPP may be the antenna connector of the UE. For frequency range 2, DL PRS-RSRPP may be measured based on the combined signal from antenna elements corresponding to a given receiver branch. For frequency range 1 and 2, if receiver diversity is in use by the UE for DL PRS-RSRPP measurements, the reported DL PRS-RSRPP value included in the higher layer parameter NR-DL-AoD-MeasElement for the first and additional measurements may be provided for the same receiver branch(es) as applied for DL PRS-RSRP measurements

“DL reference signal carrier phase (RSCP)” is defined as the phase of the channel response at the 1st path delay derived from the resource elements carrying DL PRS configured for the measurement. DL RSCP is associated with the center frequency of the DL positioning frequency layer (PFL) configured for the measurement for RRC connected, RRC inactive, and RRC idle modes. For frequency range 1, the reference point for the DL RSCP may be the antenna connector of the UE. For frequency range 2, the reference point for the DL RSCP may be the antenna of the UE.

“DL reference signal carrier phase difference (RSCPD)” is defined as the difference of DL RSCPs measured from DL PRS transmitted in a DL PFL from the transmission point (TP) j and the reference TP i. If UE reports RSCPD measurements together with RSTD measurements in a measurement report element, the reference TP for RSCPD is the same as the reference TP reported for RSTD. For frequency range 1, the reference point for the DL RSCPD may be the antenna connector of the UE. For frequency range 2, the reference point for the DL RSCPD may be the antenna of the UE.

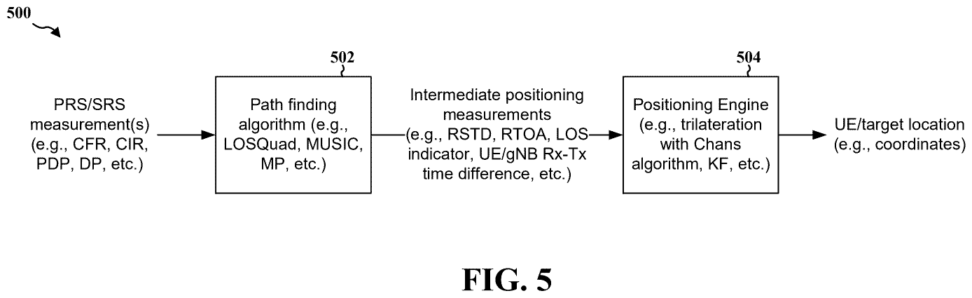

FIG. 5 is a diagram 500 illustrating an example radio access technology (RAT)-dependent positioning in accordance with various aspects of the present disclosure. For existing (e.g., classical) RAT-dependent positioning as discussed in connection with FIG. 4, as shown at 502, a positioning device/entity may be configured to input reference signal measurement(s), such as channel frequency response (CFR), channel impulse response (CIR), power delay profile (PDP), delay profile (DP) of PRS/SRS, etc., to a path finding algorithm to obtain a set of intermediate positioning measurements (e.g., RSTD, RTOA, LOS indicator, UE/gNB Rx-Tx time difference, etc.). Then, as shown at 504, the set of intermediate positioning measurements may be provided to a positioning engine (PE) to derive the location of a target, such as the coordinates of the target (which may be the positioning device itself). However, the existing RAT-dependent positioning may not be able to provide accurate positioning when the target is under non-line-of-sight (NLOS) conditions, such as when the target is in an urban dense area surrounded by tall buildings.

In some implementations, at least one artificial intelligence (AI)/machine learning (ML) (AI/ML) model may be configured/implemented at an entity/node (e.g., a UE, a network entity/node such as a base station, a location server, a location management function (LMF), etc.) for assisting the entity/node with the positioning of a UE (e.g., a target). For example, an AI/ML model may be trained to determine the position of a UE based on DL-AoA, DL-TDOA, CIR, radio frequency (RF) fingerprinting, etc. In most scenarios, using an AI/ML model may significantly improve UE positioning latency, accuracy/reliability, and/or efficiency. For example, AI/ML may enhance positioning accuracy in NLOS conditions because the AI/ML may have the capability to learns channel multipath profile and its mapping to location information.

For purposes of the present disclosure, at a high-level, an “AI/ML model” may refer to a program/algorithm that is capable of being trained on a set of data (which may be referred to as “training data”) to make certain decisions (without further human intervention), to recognize certain patterns, and/or predict certain outcomes, etc. In some examples and depending on the context, an “AI/ML model” may also refer to an actual physical model with given parameters and weights, and/or may refer to a logical model for which one or more models can be considered but all seen as one logical model from identification stand point. Similarly, depending on the context, an “AI/ML functionality” may refer to employing AI/ML to positioning without referring to an underlying model (physical and/or logical). The AI/ML functionality may still be defined/identified based on measurements of information considered for its inputs and/or outputs. In some examples, the AI/ML functionality may refer to one or more AI/ML model for which model input may refer to a specific measurement type/or and quantities. The one or more model(s) may be logical or physical. The AI/ML functionality may also refer to one or more AI/ML model for which model output may refer to a specific measurement type/location information and/or quantity. The one or more model(s) can be logical or physical. Depending on the context, sometimes the term “AI/ML model” may be used interchangeably with the term “AI/ML functionality,” and AI/ML model and AI/ML functionality may collectively be referred to as “AI/ML.”

In addition, an AI/ML model that is implemented at a UE side may be referred to as a “UE-side model” and/or “UE-side AI/ML model.” On the other hand, an AI/ML model that is implemented at a network side may be referred to as a “network-side model,” “network-side AI/ML model,” and/or (network name)-side AI/ML model (e.g., base station-side AI/ML model, LMF-side AI/ML model, etc.). In addition, positioning that is associated with a UE or a network entity/node using an AI/ML model to determine the position of the UE may be referred to as “direct AI/ML positioning,” whereas positioning that is associated with a UE or a network entity/node performing positioning related measurements using an AI/ML model (and transmitting the positioning related measurements to another entity) to determine the position of the UE may be referred to as “AI/ML assisted positioning” and/or “assisted AI/ML positioning.” Also, UE-based positioning (e.g., UE determines its own position) using at least one UE-side AI/ML model may be referred to as “direct UE AI/ML positioning” and/or “UE direct AI/ML positioning,” whereas UE-assisted positioning (e.g., a UE provides positioning measurements and a network entity, such as an LMF, determines the position for the UE based on the positioning measurements provided by the UE) using at least one UE-side AI/ML model may be referred to as “UE AI/ML assisted positioning,” “UE assisted AI/ML positioning” “AI/ML assisted UE positioning,” and/or “AI/ML UE assisted positioning,” etc. Similarly, network-based positioning (e.g., a network entity, such as an LMF, determines the position for the UE) using at least one network/LMF-side AI/ML model may be referred to as “direct network/LMF AI/ML positioning” and/or “network/LMF direct AI/ML positioning.”

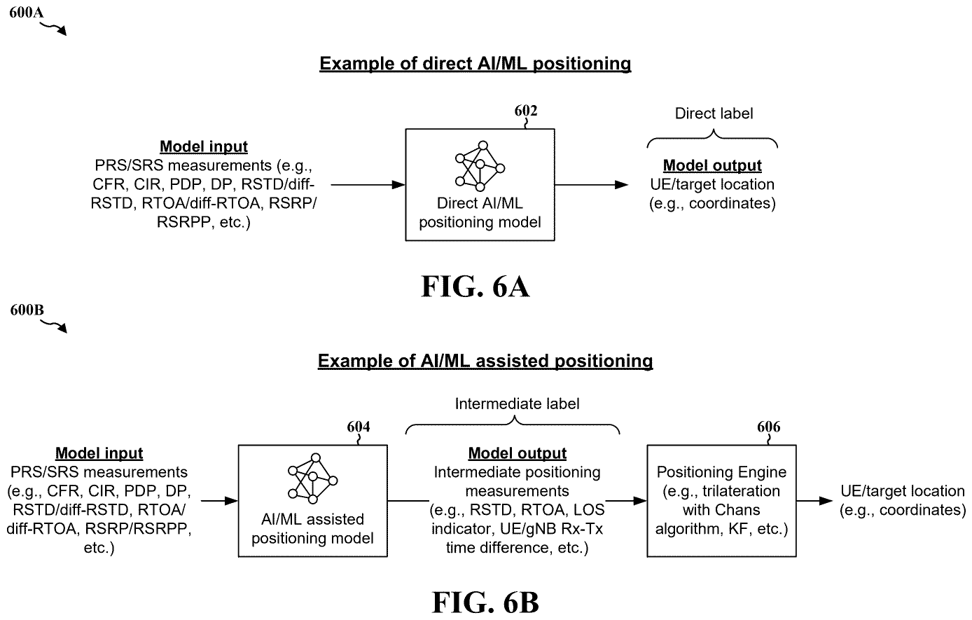

FIG. 6A is a diagram 600A illustrating an example of direct AI/ML positioning in accordance with various aspects of the present disclosure. For direct AI/ML positioning, an entity/node (e.g., a UE, a network entity/node such as a base station, a location server, etc.) may use at least one AI/ML model to determine the position of a UE or a target. For example, as shown at 602, the entity/node may input a set of PRS/SRS measurements (e.g., CFR, CIR, PDP, DP, RSTD/difference-RSTD, RTOA/difference-RTOA, RSRP/RSRPP, etc.) to a direct AI/ML positioning model, and the direct AI/ML positioning model may output the location of the UE/target, such as the coordinates of the UE/target.

FIG. 6B is a diagram 600B illustrating an example of AI/ML assisted positioning in accordance with various aspects of the present disclosure. For AI/ML assisted positioning, an entity/node (e.g., a UE, a network entity/node such as a base station, etc.) may use at least one AI/ML model to assist the measurement of reference signals (e.g., positioning reference signals such as PRS, SRS, etc.). Then, the entity/node may transmit the reference signal measurements to a location server, such as an LMF. In response, the location server may determine the position of a UE/target based on a non-AI/ML mechanism/algorithm, or based on using another AI/ML model to determine the position of the UE/target. For example, as shown at 604, the entity/node may input a set of PRS/SRS measurements (e.g., CFR, CIR, PDP, DP, RSTD/difference-RSTD, RTOA/difference-RTOA, RSRP/RSRPP, etc.) related to a UE/target to an AI/ML assisted positioning model, and the AI/ML assisted positioning model may output a set of intermediate positioning measurements (e.g., RSTD, RTOA, LOS indicator, UE/gNB Rx-Tx time difference, etc.). Then, as shown at 606, the set of intermediate positioning measurements may be provided to a positioning engine (PE) (or another AI/ML model) to derive the location of the UE/target, such as the coordinates of the UE/target (which may be the entity/node itself).

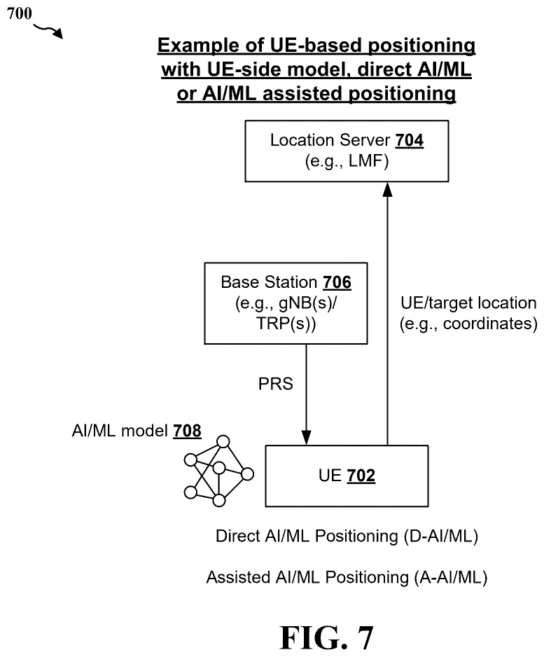

FIG. 7 is a diagram 700 illustrating an example of UE-based positioning with a UE-side AI/ML model, direct AI/ML or AI/ML assisted positioning in accordance with various aspects of the present disclosure. In one implementation, a UE 702 may be associated with at least one AI/ML model 708, and the UE 702 may use the at least one AI/ML model 708 to perform the direct AI/ML positioning and/or the assisted AI/ML positioning based on downlink (DL) reference signals, such as positioning reference signals (PRSs). For example, the UE 702 may receive and measure a set of PRSs transmitted from a base station 706 (this may also be one or more base stations and/or one or more TRPs), such as measuring the reference signal received power (RSRP), channel impulse response (CIR), DL-AoD, reference signal time difference (RSTD), time of arrival (ToA), and/or time of flight (ToF) of the set of PRSs, etc., which may be collectively be referred to as “PRS measurement(s)” and/or “PRS-based measurement(s).” In some examples, the UE 702 may use the at least one AI/ML model 708 for measuring the set of PRSs (e.g., for assisted AI/ML positioning). In some examples, based on the PRS measurement(s), the UE 702 may use the at least one AI/ML model 708 for determining its position (e.g., for direct AI/ML positioning). Note in this assisted AI/ML positioning example, the UE 702 may use the at least one AI/ML model 708 for performing PRS measurements, and the UE 702 may determine its position based on the PRS measurements without the assistance of an AI/ML model.

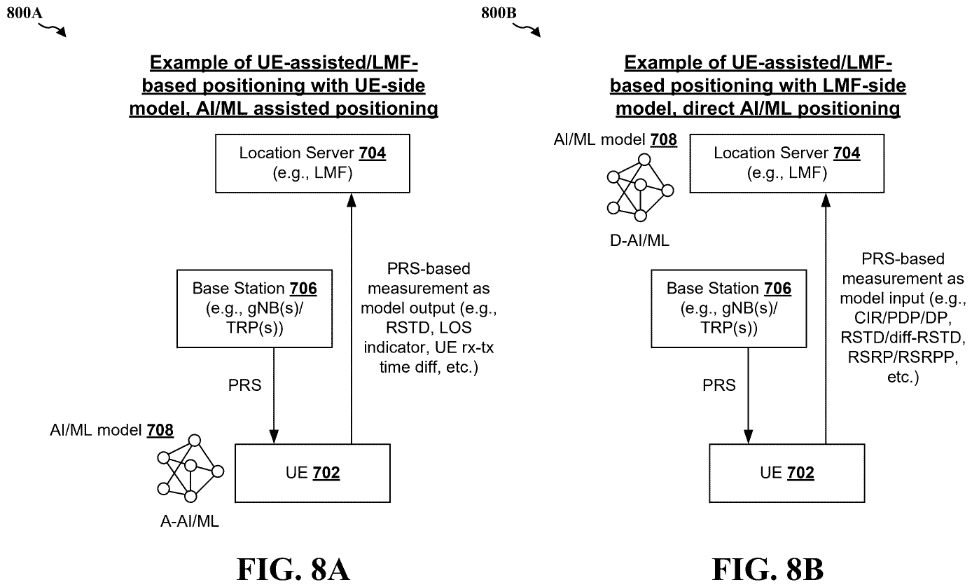

FIG. 8A is a diagram 800A illustrating an example of UE-assisted/LMF-based positioning with a UE-side AI/ML model, AI/ML assisted positioning in accordance with various aspects of the present disclosure. In another implementation, a UE 702 may be associated with at least one AI/ML model 708, and the UE 702 may use the at least one AI/ML model 708 to perform or assist measurement(s) of DL reference signals. For example, the UE 702 may receive and measure a set of PRSs transmitted from a base station 706 (this may also be one or more base stations and/or one or more TRPs) with the assistance of the at least one AI/ML model 708, which may be referred to as “PRS-based measurement(s).” Then, the UE 702 may transmit the PRS-based measurement(s) (e.g., the output of the at least one AI/ML model 708 such as the RSTD, the LOS indicator, the UE Rx-Tx time difference, etc.) to a location server 704, such as an LMF. In response, the location server 704 may determine the position of the UE 702 based on the PRS-based measurement(s) (with or without suing an AI/ML model).

FIG. 8B is a diagram 800B illustrating an example of UE-assisted/LMF-based positioning with an LMF-side AI/ML model, direct AI/ML positioning in accordance with various aspects of the present disclosure. In another implementation, a UE 702 may not include a UE-side AI/ML model, and a location server 704 may use at least one AI/ML model 708 to determine the position of the UE 702. For example, the UE 702 may receive and measure a set of PRSs transmitted from a base station 706, and the UE 702 may transmit the PRS-based measurement(s) (e.g., CIR/PDP/DP, RSTD/difference-RSTD, RSRP/RSRPP, etc.) to the location server 704, such as an LMF. Based on the PRS-based measurement(s) from the UE 702, the location server 704 may use the PRS-based measurement(s) as an input to at least one AI/ML model 708, and receive the position of the UE 702 as an output from the at least one AI/ML model 708.

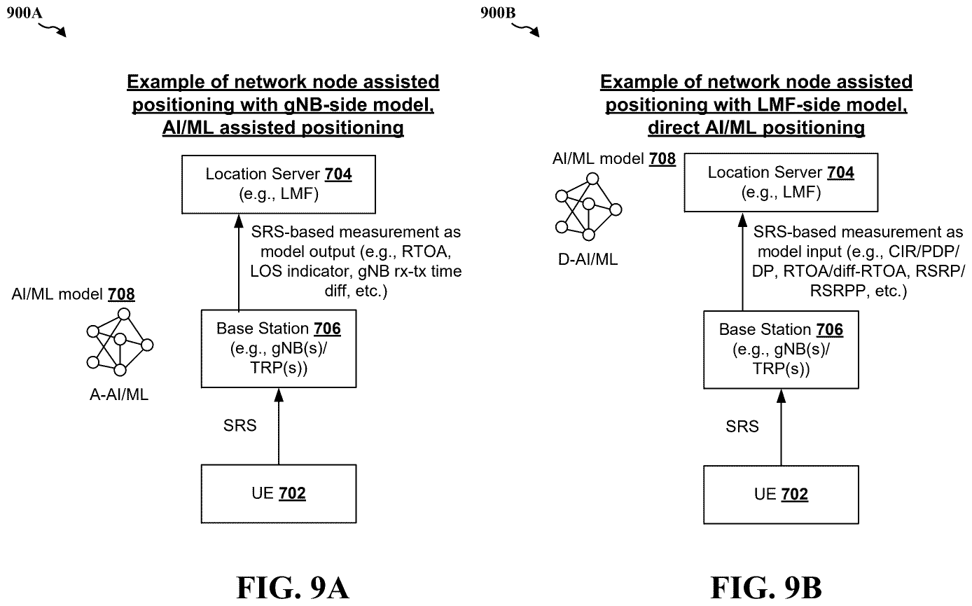

FIG. 9A is a diagram 900A illustrating an example of network (e.g., NG-RAN) node assisted positioning with a base station (gNB)-side AI/ML model, AI/ML assisted positioning in accordance with various aspects of the present disclosure. In another implementation, a network node, such as a base station 706, may be associated with at least one AI/ML model 708, and the base station 706 may use the at least one AI/ML model 708 to assist measurement(s) of uplink (UL) reference signals, such as sounding reference signals (SRSs). For example, the UE 702 may transmit a set of SRSs to the base station 706 (this may also be one or more base stations and/or one or more TRPs), and the base station 706 may receive and measure the set of SRSs (which may be referred to as “SRS-based measurement(s)”) with the assistance of the at least one AI/ML model 708. Then, the base station 706 may transmit the SRS-based measurement(s) (e.g., the output of the at least one AI/ML model 708 such as the RTOA, LOS indicator, gNB Rx-Tx time difference, etc.) to a location server 704, such as an LMF. In response, the location server 704 may determine the position of the UE 702 based on the SRS-based measurement(s) (with or without suing an AI/ML model).

FIG. 9B is a diagram 900B illustrating an example of network (e.g., NG-RAN) node assisted positioning with LMF-side AI/ML model, direct AI/ML positioning in accordance with various aspects of the present disclosure. In another implementation, a network node, such as a base station 706 (this may also be one or more base stations and/or one or more TRPs), may not include an AI/ML model, and a location server 704 may use at least one AI/ML model 708 to determine the position of a UE 702. For example, the UE 702 may transmit a set of SRSs to the base station 706, and the base station 706 may receive and measure the set of SRSs. Then, the base station 706 may transmit the SRS-based measurement(s) to the location server 704, such as an LMF. Based on the SRS-based measurement(s) from the base station 706, the location server 704 may use the SRS-based measurement(s) as an input to at least one AI/ML model 708, and receive the position of the UE 702 as an output from the at least one AI/ML model 708. For purposes of the present disclosure, positioning described in connection with FIGS. 7, 8A, and 8B may be referred to as AI/ML positioning based on DL reference signals, and positioning described in connection with FIGS. 9A and 9B may be referred to as AI/ML positioning based on UL reference signals.

In some implementations, for direct AI/ML positioning as described in connection with FIGS. 8B and 9B, type(s) of measurement(s) that may be used as (suitable/potential) input for AI/ML model inference considering performance impact and associated signaling overhead may include channel impulse response (CIR), power delay profile (PDP), reference signal receive power (RSRP), reference signal received path power (RSRPP), and/or reference signal time difference (RSTD), etc. For AI/ML assisted positioning with UE-assisted and network node-assisted positioning described in connection with FIGS. 8A and 9A, respectively, measurement report to carry AI/ML model (suitable/potential) output to a location server such as an LMF may include ToA, path phase, RSTD, line-of-sight (LOS)/non-line-of-sight (NLOS) indicator, RSRPP, and/or soft information/high resolution of RSTD, etc. In some examples, AI/ML model inference output that may provide performance benefits may include timing estimation (note the report to LMF may be derived based on and maybe different from the model inference output) and/or LOS/NLOS indicator.

For network node assisted positioning such as described in connection with FIG. 9A, at least LOS/NLOS indicator and/or timing information may be supported by a base station (e.g., the base station 706) for reporting (e.g., to a location server such as the location server 704). If LOS/NLOS indicator is reported by the base station, the indicator may be reported as a soft indicator or a hard indicator depending on implementations. If timing information is reported, the base station may be configured to report the timing information via UL RTOA or gNB Rx-Tx time difference. Similarly, for UE-assisted positioning such as described in connection with FIG. 8A, at least LOS/NLOS indicator and/or timing information may be supported by a UE (e.g., the UE 702) for reporting (e.g., to a location server such as the location server 704). If LOS/NLOS indicator is reported by the UE, the indicator may be reported as a soft indicator or a hard indicator depending on implementations. If timing information is reported, the base station may be configured to report the timing information via DL RSTD or UE Rx-Tx time difference.

For AI/ML based positioning such as described in connection with FIG. 9B, at least (1) timing information, and/or (2) paired timing information and power information may be supported by a base station (e.g., the base station 706) for reporting time domain channel measurements. Similarly, for AI/ML based positioning such as described in connection with FIG. 8A, at least (1) timing information, and/or (2) paired timing information and power information may be supported by a UE (e.g., the UE 702) for reporting time domain channel measurements (e.g., to a location server such as the location server 704 or an LMF).

In addition to various positioning mechanisms discussed in connection with FIG. 4, a wireless device may also detect/locate/track a target based on sensing. For purposes of the present disclosure and in the context of positioning, sensing may refer to a process of detecting, measuring, and interpreting information about an object's range, cross-range, location, orientation, speed, acceleration, or movement in a space. For example, a wireless device (e.g., a TRP, a base station, a component of the base station, a UE, etc.) may have radar capabilities (which may be referred to as the “radio frequency (RF) sensing” and/or the “cellular-based RF sensing,” where the wireless device may transmit radar reference signals (RRSs) and measure the RRSs reflected from one or more objects. Based at least in part on the measurement of the reflected RRSs, the wireless device may determine or estimate a distance (and/or a direction) between the wireless device and the one or more objects. In another example, a first wireless device may also receive RRSs transmitted from a second wireless device, where the first wireless device may determine or estimate a distance (and/or a direction) between the first wireless device and the second wireless device based at least in part on the received RRS. As such, in some examples, RF sensing techniques may be used for UE positioning and/or for assisting UE positioning.

For purposes of the present disclosure, a device that is capable of performing RF sensing (e.g., transmitting and/or receiving RRS for detecting an object or for estimating the distance between the device and the object) may be referred to as a “sensing node” or an “RF sensing node.” For example, a sensing node/RF sensing node may be a UE, a base station, a component of the base station, a TRP, a device capable of transmitting RRS, and/or a device configured to perform radar functions, etc. In some examples, the term “sensing node” and “RF sensing node” may also be used interchangeably with the term “radar.” An RF sensing measurement may refer to any measurements that are associated with RF sensing.

Due to an increased amount of bandwidth (BW) being allocated for cellular communications systems (e.g., 5G and beyond) and an increased amount of applications being introduced with cellular communications systems, joint communication and RF sensing, which may also be referred to as integrated sensing and communication (ISAC) and/or joint communication-radar (JCR), have become an important feature for many cellular systems. For example, a wireless device may be configured to transmit communication signals (e.g., PDSCH, PUSCH, PSSCH, etc.) with radar signals (e.g., RRS, frequency modulated continuous wave (FMCW) signals, etc.) together or close in time (e.g., based on TDM, FDM, SDM, etc.). In addition, OFDM waveform (or its variants) may be used as the waveform for the ISAC/JCR as the OFDM waveform may enable in-band multiplexing with other cellular reference signals and physical channels. As such, the radar signals may be multiplexed with communication signals based on OFDM waveform. For purposes of the present disclosure, a wireless device that performs an RF sensing based on OFDM waveform(s) or transmits RRS based on OFDM waveform(s) may be referred to as an “OFDM radar.”

In the context of ISAC or ISAC channel modelling, the following terms and definitions may be used.
(1) Sensing transmitter: a wireless device (e.g., a TRP, a UE, etc.) that sends out the sensing signal which the sensing service may use in its operation. A sensing transmitter may be located in the same or different wireless device (e.g., same or different TRP or UE) as the sensing receiver.
(2) Sensing receiver: a wireless device (e.g., a TRP, a UE, etc.) that receives the sensing signal which the sensing service may use in its operation. A sensing receiver may be located in the same or different TRP or a UE as the sensing transmitter.
(3) Sensing target: target that need to be sensed by deriving characteristics of the objects within the environment from the sensing signal.
(4) Background environment: background (clutter and/or environmental objects) that are not the sensing target(s).
(5) Mono-static sensing: sensing where a sensing transmitter that transmits a sensing signal and a sensing receiver that receives the sensing signal are co-located in the same wireless device (e.g., in the same TRP or UE).
(6) Bi-static sensing: sensing where a sensing transmitter that transmits a sensing signal and a sensing receiver that receives the sensing signal are not co-located in the same wireless device (e.g., not co-located in the same TRP or UE).
(7) Multi-static sensing: sensing where there are multiple sensing transmitters and/or multiple sensing receivers, for a sensing target.
(8) Sensing signal: transmissions on a radio interface (e.g., the 3GPP radio interface) that may be used for sensing purposes.

Sensing operation may be implemented in a couple of different ways, from radar like sensing where the sensing transmitter and sensing receiver are co-located in the same entity, which may be referred to as the monostatic sensing, to have the sensing receiver and sensing transmitter in different entities, which may be referred to as the bistatic sensing. A more advanced scenario with multiple sensing transmitters and receivers is also possible, which may be referred to as the multi-static sensing. The reflections of the sensing signal sent from the sensing transmitter are received by the sensing receiver and processed to obtain characteristics of the sensed object and its environment (e.g., location).

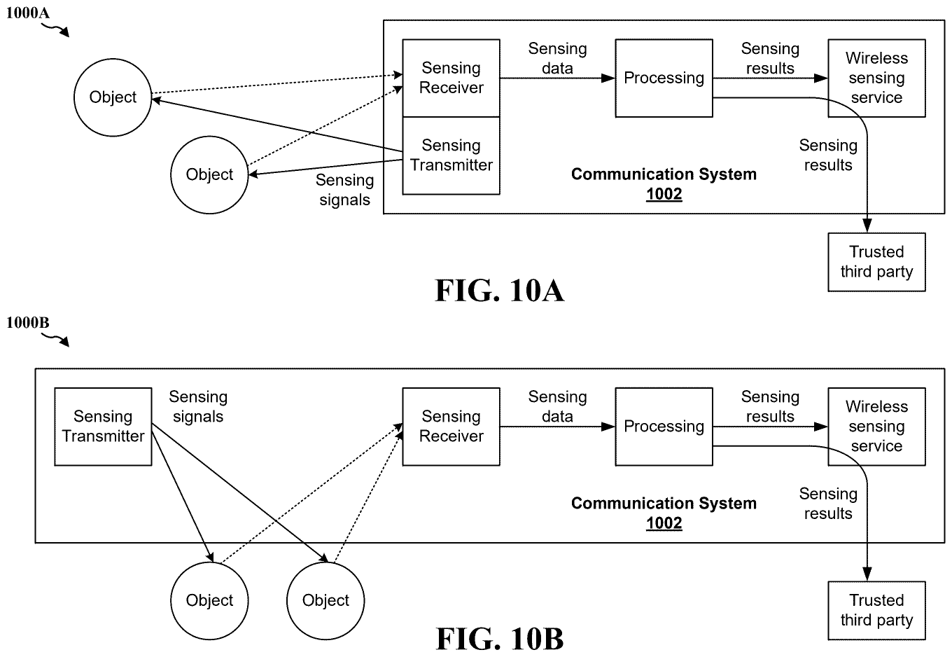

FIG. 10A is a diagram 1000A illustrating an example of sensing with co-located sensing receiver and sensing transmitter (e.g., monostatic sensing) in accordance with various aspects of the present disclosure. Under mono-static sensing, the sensing transmitter (e.g., the Tx antenna panel) and the sensing receiver (e.g., the Rx antenna panel) of the RF sensor are co-located, such as in the same communication system 1002 (e.g., the same TRP or UE). Thus, the transmission and reception of the sensing signals may be performed by one device. An advantage of mono-static sensing is that it may not specify Tx/Rx (transmitter/receiver) pairing/grouping. However, mono-static sensing may specify self-interference mitigation as the same wireless device is used for transmitting both sensing signals and communication signals.

FIG. 10B is a diagram 1000B illustrating an example of sensing with separated sensing receiver and sensing transmitter (e.g., bistatic/multi-static sensing) in accordance with various aspects of the present disclosure. Under bistatic/multi-static sensing, the sensing transmitter and the sensing receiver may be separated (e.g., on different wireless devices and/or locations). For example, the sensing transmitter (e.g., the Tx antenna panel) of the communication system 1002 may transmit sensing signals from a first location, and the sensing signals reflected from one or more objects may be received by the sensing receiver (e.g., the Rx antenna panel) of the communication system 1002 at a second location.

For the purposes of the present disclosure and in the context of ISAC, the following terms and definitions may be used.
(1) Sensing data (or 3GPP sensing data): data derived from radio signals (e.g., 3GPP radio signals) impacted (e.g., reflected, refracted, diffracted) by an object or environment of interest for sensing purposes, and optionally processed within a wireless communication system (e.g., the 5G/6G system).
(2) Wireless sensing (e.g., 5G wireless sensing): a feature providing capabilities to get information about characteristics of the environment and/or objects within the environment (e.g., shape, size, orientation, speed, location, distances or relative motion between objects, etc.) using radio frequency signals (e.g., NR radio frequency signals), which, in some cases, may be extended by information created via previously specified functionalities in Evolved Packet Core (EPC) and/or Evolved Universal Terrestrial Radio Access Network (E-UTRAN).
(3) non-3GPP sensing data: data provided by non-3GPP sensors (e.g., video, LiDAR, sonar) about an object or environment of interest for sensing purposes.
(4) Sensing assistance information: information that is provided to a wireless communication system (e.g., the 5G system) from a trusted third-party and may be used to support the derivation of a sensing result. This information may not contain 3GPP sensing data. Examples of sensing assistance information may include map information, area information, a UE ID attached to or in the proximity of the sensing target, UE position information, UE velocity information etc.
(5) Sensing contextual information: information that is exposed with the sensing results by a wireless communication system (e.g., the 5G system) to a trusted third-party which provides context to the conditions under which the sensing results were derived. This information may not contain 3GPP sensing data. Example sensing contextual information may include map information, area information, time of capture, UE location and ID. This contextual information can be required in scenarios where the sensing result is to be combined with data from other sources outside the wireless communication system.
(6) Sensing group: a set of sensing transmitters and sensing receivers whose location is known and whose sensing data may be collected synchronously.
(7) Sensing receiver: a sensing receiver is an entity that receives the sensing signal which the sensing service will use in its operation. A sensing receiver may be part of a RAN node or a UE. A sensing receiver may be located in the same or different entity as the sensing transmitter.
(8) Sensing result: processed sensing data (e.g., 3GPP sensing data) requested by a service consumer.
(9) Sensing signals: transmissions on a radio interface (e.g., the 3GPP radio interface) that may be used for sensing purposes.
(10) Sensing transmitter: a sensing transmitter is the entity that sends out the sensing signal which the sensing service will use in its operation. A sensing transmitter may be part of a RAN node or a UE. A sensing transmitter may be located in the same or different entity as the sensing receiver.
(11) Target sensing service area: a cartesian location area that is to be sensed by deriving characteristics of the environment and/or objects within the environment with certain sensing service quality from the impacted (e.g., reflected, refracted, diffracted) radio signals (e.g., 3GPP radio signals). This may include both indoor and outdoor environments.

RF sensing may be used for extending positioning capabilities for various positioning related applications and devices. Factors affecting sensing performance may include radar cross-section (RCS), mobility, and clutter/scattering patterns, etc. Most current network designs may focus primarily on data transmission, and the radio channel model defined to cover frequencies up to 100 GHz was developed. Although RAT-based positioning is supported, the systems may not offer the in-built capability to detect objects not connected to the network. The focus of future sensing may include defining channel modelling aspects to support object detection and/or tracking, and aim at a common modelling framework capable of detecting and/or tracking the following example objects and to enable them to be distinguished from unintended objects: unmanned aerial vehicles (UAVs), humans indoors and outdoors, automotive vehicles (at least outdoors), automated guided vehicles (e.g., in indoor factories), and/or objects creating hazards on roads/railways, with a minimum size dependent on frequency, etc. Frequencies from 0.5 to 52.6 GHz may be the primary focus, with the assumption that the modelling approach may scale to 100 GHz.

Example sensing applications, devices, or uses cases may include: (1) transportation (e.g., intrusion detection on a highway, sensing assisted automotive maneuvering and navigation, smart parking and assistance, etc.), (2) unmanned aerial vehicle (UAV) (e.g., UAV flight trajectory tracing, sensing for UAV intrusion detection, etc.), (3) smart city (e.g., rainfall monitoring, tourist spot traffic management, flooding awareness, weather forecasting, public safety search and rescue, etc.), (4) smart home (e.g., intruder detection in smart home, gesture recognition, XR streaming, etc.), (5) health monitoring (e.g., monitoring vital signs and health related measures, sleep/health monitoring, etc.), and/or (6) smart factory (e.g., automated guided vehicles (AGV) detection and tracking in factories, etc.).

Depending on implementations, sensing may offer various key performance indicators (KPIs), such as accuracy of positioning (horizontal/vertical), accuracy of range and cross-range of target, accuracy of AoA of a target (azimuth/elevation), accuracy of velocity (horizontal/vertical), sensing range/cross-range resolutions, sensing velocity resolution, sensing angle resolution, sensing latency, sensing refreshing rate, receiver operating characteristics (ROC) (e.g., misdetection and false alarm probabilities, etc.), confidence interval/level of sensing, and/or target discrimination, etc.

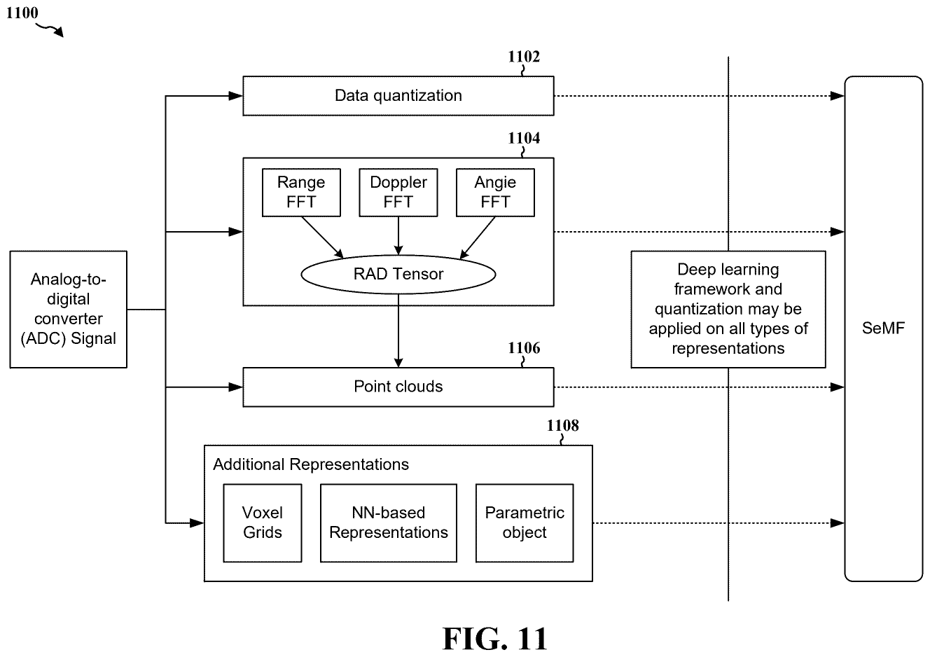

FIG. 11 is a diagram 1100 illustrating an example sensing data signal processing flow from analog-to-digital converter (ADC) samples to progressively higher-level data representations associated with an integrated sensing and communication (ISAC) in accordance with various aspects of the present disclosure. From low levels to high levels, the data types may be listed as raw data, range-angle-doppler (RAD) tensor, point cloud, and grid map. Learning-based frameworks may also be adopted which support the encoding and decoding of different representation types, and additional quantization may be adopted to reduced data size.

For example, as shown at 1102 (data quantization), at the lowest level, sampling and quantization of the sensing signal may be the initial steps. To reduce the volume of data that is to be processed, various techniques may be implemented. Some methods, such as compressed sensing, may exploit the sparsity of the signal to acquire it at a lower sampling rate. Other methods may use low-bit quantization to reduce complexity and power consumption at the TRP. In particular, the power consumption of ADCs in hybrid architectures may grow exponentially to the number of quantization levels, thus elevating the importance of ADC quantization. In extreme cases, sampling may be done with just one bit per sample, significantly reducing the data volume to be transmitted by the TRP. Note that data quantization may be combined with other representations, such as range-angle-doppler (RAD) tensors, point clouds and so on. It may also be used as the format of data to be exchanged in the case of signal-level fusion where the sensing data is sent directly to the fusion center without performing further local processing.

As shown at 1104 (e.g., RAD tensors), range-angle and range-doppler maps may be fundamental data representations in radar signal processing. These maps may provide a structured way to visualize and analyze the spatial and velocity information of detected targets. In the context of ISAC, these maps may be important for tasks like target detection, localization, and tracking.

As shown at 1106, point clouds may be a versatile and widely used data representation method in various sensing applications, including radar, LiDAR, and computer vision. In the context of ISAC, point clouds may provide a spatial representation of multiple targets by capturing discrete points in a three-dimensional space. Each point in the cloud may contain information about the target's range, velocity, azimuth angle, and elevation angle.

As shown at 1108, additional representations such as voxel grids, deep learning-based representations, and/or parametric object representations may also be used. Voxel grids are another form of data representation where the 3D space is divided into a grid of volumetric pixels (voxels). Each voxel may store information such as occupancy, intensity, or other attributes. Voxel grids may be particularly useful for representing the environment in autonomous driving and robotics applications. They may provide a structured representation that may be easily processed by algorithms but can be memory intensive. For deep learning-based representations, recent advancements in deep learning have led to the development of improved data representations. For instance, radar data may be transformed into images or tensors that are fed into convolutional neural networks (CNNs) for tasks such as object detection and classification. These representations may leverage the power of deep learning to extract high-level features from raw data, improving the accuracy and robustness of sensing systems. Interesting work has also been done using variational auto-encoders (VAE) which project the input data into a distribution over the latent space. In particular, the following forms of deep learning representations may be considered: embeddings, feature vectors (outputs of feature extraction layers), and layer weights, etc. For parametric object representations, by performing object segmentation over the obtained point clouds, scene information may be conveyed with much fewer data. This operation may typically involve two steps: (i) employing clustering algorithms to separate the point cloud into groups that correspond to different environment objects; and (ii) unifying the points of each group to a compact representation, therefore unveiling the shape of each object. To describe shapes of 3D objects, multiple approaches may be taken, such as polygon representations (represented as the convex hulls of each point cloud group), wireframes (interconnected sets of edges), or general parametric shapes, where each shape is represented by the set of its geometric parameters (e.g., center and radius for 3D balls). While accurately representing real objects with geometrical shapes may present its own challenges, once such representation is obtained, very few bytes of information may be transmitted to describe the complete scene.

For purposes of the present disclosure, sensing that is obtained/derived using an AI/ML model or functionality may collectively be referred to as “AI/ML sensing.” For example, under the AI/ML sensing, a set of sensing measurements obtained from one or more sensors (e.g., measurements of radar signals by sensor(s)/receiver(s)) may be input into an AI/ML model/functionality to output the location of one or more targets. In another example, an AI/ML model/functionality may be used to receive raw input(s) from sensor(s) and out a set of sensing measurements that may be used for assisting the sensing of one or more targets (e.g., similar to the AI/ML assisted positioning model that provides intermediate positioning measurements as described in connection with FIG. 6B). An AI/ML sensing model/functionality may be configured to output a sensing result or a key performance indicator (KPI). For example, a target's (passive object) range, cross-range, location, speed, acceleration, presence indicator, angle info (e.g., AoA, AoA-A (azimuth)/-Z (zenith), etc., or information related to target material, shape, radar cross section (RCS), etc.

In recent years, AI/ML techniques have also been developed and implemented for improving performance and/or reducing complexity in wireless networks, such as using AI/ML for channel state information (CSI) feedback (CSF), beam management, and/or positioning (as discussed above), etc.

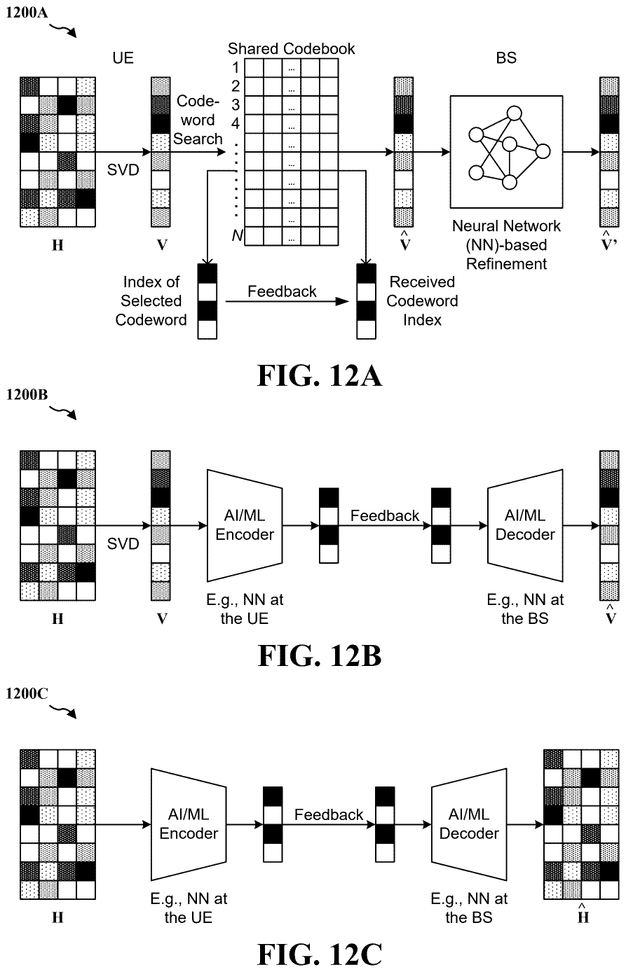

FIGS. 12A, 12B, and 12C are diagrams 1200A, 1200B, and 1200C, respectively, illustrating example uses of AI/ML for the CSI feedback in accordance with various aspects of the present disclosure. Depending on implementations, the use of AI/ML for the CSI feedback may be categorized into three categories: (1) one-sided refinement for implicit CSI feedback, (2) two-sided enhancement for implicit feedback, and/or (3) two-sided enhancement for explicit feedback.

As shown by the diagram 1200A of FIG. 12A, for the (1) one-sided refinement for implicit CSI feedback, a UE may be configured to use AI/ML model(s) to help determine the best or most suitable reported precoding matrix indicator (PMI), and a base station (e.g., gNB) may be configured to use AI/ML model(s) to refine the selected channel codeword (precoding matrix) reported by the UE. Both approaches may be implementation-based, and there may be no specifications change impact.

As shown by the diagram 1200B of FIG. 12B, for the (2) two-sided enhancement for implicit feedback (which may also be referred to as autoencoder-based two-sided enhancement for implicit feedback), the PMI reporting by the UE may be replaced by a bit stream, representing the UE encoding of the PMI. The base station may be configured to decode the received bitstream to obtain the original precoding matrix. This approach may involve specifications impact to standardize the bitstream encoding/reporting.

As shown by the diagram 1200C of FIG. 12C, for the (3) two-sided enhancement for explicit feedback (which may also be referred to as autoencoder-based two-sided enhancement for explicit feedback), the UE may be configured to feed back the entire channel H to the base station using an NN-based encoder which generates a sequence of bits. The BS may be configured to decode the received sequence of bits into the channel estimate Ĥ. This approach may involve specifications impact to standardize the bitstream encoding/reporting

Given the large information amount in the channel, CSI feedback in the third category (e.g., as discussed in connection with the diagram 1200C of FIG. 12C) may be larger than the first category and/or the second category (e.g., as discussed in connection with the diagram 1200A of FIG. 12A and the diagram 1200B of FIG. 12B). As such, some wireless communication developers have appeared to favor the second category (i.e., the implicit feedback) for the CSI feedback use case. On the other hand, in the context of positioning, reporting a richer representation of the channel has also been considered as well. For example, some developers have proposed the use of explicit feedbacks for DL/UL measurements, such as for reporting SRS measurements for LMF AI/ML positioning models, for compressing PRS measurements and reporting for LMF-sided AI/ML positioning models, etc. Some discussions have also been studying ways of reporting more samples/paths per CIR for enhanced performance.

RF sensing has been expected to be widely adopted for future generations of wireless systems (e.g., for 5G advanced, 6G, etc.), where studies have been conducted to evolve the stochastic channel model to support future sensing simulations or applications. In the context of RF sensing, a sensing node may be configured to measure the channel over an extended window of time. This window of time may typically be referred to as a coherent processing interval (CPI) in the radar literature. After collecting the sequence of channel measurements, the sensing node may perform the sensing processing, e.g., range-Doppler (R-D) processing followed by constant false alarm rate (CFAR), range-Doppler-angle processing, etc. The sensing node may be expected/configured to report (1) the dominant components in the range-Doppler or range-angle or range-Doppler-angle map, and/or (2) a target presence indication.

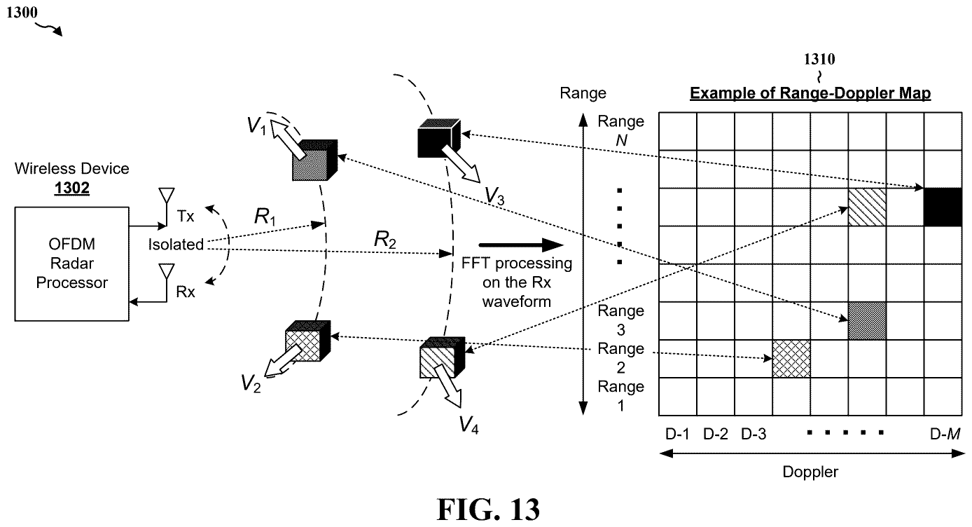

FIG. 13 is a diagram 1300 illustrating an example of sensing signal processing in accordance with various aspects of the present disclosure. Assuming a wireless device 1302 (e.g., a UE, a TRP, etc.) is configured to perform monostatic sensing (e.g., as discussed in connection with FIG. 10A). The wireless device 1302 may be configured to measure M consecutive reference signal (RS) symbols (e.g., PRS symbols, SRS symbols, etc.). Based on the RS/channel measurements, the wireless device 1302 may derive a range-doppler (R-D) map, which may be obtained by performing a two FFT operations on the matrix combining all the RS/channel measurements. For example, as shown at 1310, the R-D map derived by the wireless device 1302 may contain four “strong” components, which the the wireless device 1302 may report to the sensing server.

In some implementations, the wireless device 1302 may be configured to use a (configurable) threshold to determine if an entry in the R-D map is “strong” enough to be reported. However, using a threshold may be error-prone. There may be cases when the threshold is inadequate and the wireless device 1302 misses reporting entries of the R-D map that are useful for the sensing. On the other hand, if the wireless device 1302 is configured to report the entire R-D map, the reporting may be inefficient and the amount of information may scale with the granularity of the reporting. For example, a higher reporting granularity may provide a higher accuracy at the expense of a higher overhead compared to a lower reporting granularity.

Aspects presented herein may improve the overall performance of RF sensing and positioning by enabling wireless device(s) performing RF sensing and/or positioning to provide a plurality of RS/channel measurements using an explicit feedback, such as described in connection with FIG. 12B. For example, in one aspect of the present disclosure, a receiving/reception (Rx) sensing node may be configured to measure multiple instances of the RS/channel to a transmitting/transmission (Tx) sensing node. For purposes of the present disclosure, an Rx sensing node may refer to the sensing node that receives the sensing signal, and an Tx sensing node may refer to the sensing node that transmits the sensing signal. Depending on implementations, the Rx sensing node and the Tx sensing node may be the same sensing node (e.g., for monostatic sensing as discussed in connection with FIG. 10A), or may be different sensing nodes (e.g., for bistatic/multi-static sensing as discussed in connection with FIG. 10B). The Rx sensing node may perform pre-processing on the collection of RS/channel measurements (e.g., two-dimensional (2D) fast Fourier transform (FFT) to generate the Range-Doppler map). The Rx sensing node may compress its RS/channel measurements using an AI/ML encoder (e.g., an AI/ML model/functionality) to generate a sequence of bits representing the RS/channel measurements. Then, the Rx sensing node may report (e.g., transmit, indicate, etc.) the sequence of bits to a server (e.g., an entity that receives the sequence of bits). The server may be configured to reconstruct the channels using a corresponding/matching AI/ML decoder (e.g., an AI/ML model/functionality), or uses the feedback bits as an input for a processing algorithm (e.g., a sensing algorithm that fuses inputs from multiple sensing nodes and detects target(s). As such, aspects presented herein may significantly reduce the overhead of channel feedback.

Aspects presented herein may be suitable for various scenarios in wireless communications. For example, a base station may request a UE to compress and to report a plurality of channel measurements, performed on a set of reference signals (e.g., a set of tracking reference signals (TRSs)). In another example, a sensing server may configure a sensing node (e.g., a UE or a TRP) to compress and to report a plurality of channel measurements, performed on a set of PRS/SRS signals. Note that applying a single-instance AI/ML model to compress channels N times may not be equivalent to using a dedicated N-instance AI/ML model for channel compression (e.g., compressing multiple/N channels at one time), as the former approach may miss important aspects such as Doppler, whereas the latter may effectively capture the Doppler characteristics, which is a form of signal correlation in the time domain across the N instances. Also, using an N-instance channel compression model may effectively capture hidden correlations in the channel that are otherwise hard to extract (e.g., there may be hidden correlations that can be efficiently extracted by the AI/ML model).

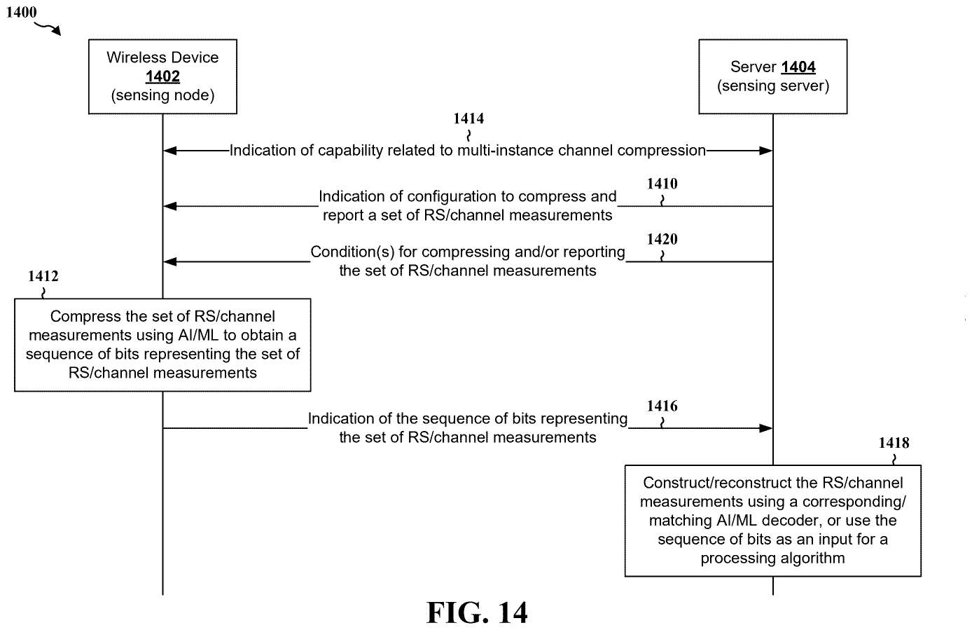

FIG. 14 is a communication flow 1400 illustrating an example of an enhanced channel feedback for RF sensing in accordance with various aspects of the present disclosure. The numberings associated with the communication flow 1400 do not specify a particular temporal order and are merely used as references for the communication flow 1400.

At 1410, a server 1404 may be configured to transmit, to a wireless device 1402, an indication of a configuration to compress and to report a set of RS/channel measurements (note depending on the context, “RS measurement” and “channel measurement” may refer to the same measurement and may be used interchangeably). Depending on implementations, the wireless device 1402 may be a sensing node, a (first) user equipment (UE), a (first) base station, or a transmission reception point (TRP) of the (first) base station, etc. The server 1404 may be a sensing server, a (second) base station, a sensing management function (SeMF), a location management function (LMF), or a (second) UE, etc. In other words, a sensing node (denoted as the wireless device 1402 for purposes of illustration) may receive a configuration from a configuring entity (denoted as the server 1404 for purposes of illustration) to measure and report a compressed representation of a plurality of RS/channel measurements, performed on a plurality of reference signals (RSs). The configuring entity may be a base station/gNB, a sensing server, an LMF, a UE, etc., and the sensing node may be a UE or a TRP, etc.

The compressed RS/channel measurements (which may also be referred to as the “compressed representation of the RS/channel measurements”) may be configured to be in a form of explicit channel feedback. In some implementations, the configuration may also indicate a set of RSs over which the RS/channel measurements are specified to be done. For example, if the wireless device 1402 is a UE, the configuration may include a set of PRS resources or a PRS resource set, a PRS resource configured with a defined certain periodicity, a set of TRS signals, etc. On the other hand, if the wireless device 1402 is a TRP, the configuration may include a set of SRS resources or an SRS resource set, an SRS resource configured with a defined certain periodicity, etc.

In some implementation, the configuration may also indicate a set of pre-processing steps/mechanisms to be applied by the wireless device 1402 to the set of RS/channel measurements before passing the set of RS/channel measurements to an AI/ML encoder (discussed below). For example, the configuration may indicate the wireless device 1402 to perform a 2D FFT operation on the CFR measurements.

At 1412, based on the configuration (i.e., received at 1410), the wireless device 1402 may be configured to compress the set of RS/channel measurements using at least one AI/ML model/functionality (referring to as the “AI/ML encoder” hereafter) to obtain a sequence of bits representing the set of RS/channel measurements. This may include receiving a set of RSs from another entity, and measure the set of RSs to obtain the set of RS/channel measurements (not shown in the communication flow 1400). In addition, the AI/ML encoder may have the capability to measure multiple RSs from a source (which may be referred to as the “N-instance RS/channel compressor” or “multi-instance RS/channel compressor,” etc.).

Depending on implementations, in on example, the AI/ML encoder may be a standard specified AI/ML model/functionality which may be available/implemented at the wireless device 1402. As such, the server 1404 may request/configure the wireless device 1402 to use a specific AI/ML encoder by indicating/specifying the ID corresponding to the AI/ML encoder in the configuration. In another example, the AI/ML encoder may be provided by the server 1404. For example, along with the configuration (transmitted at 1410) or in a separated signaling, the server 1404 may provide the AI/ML encoder to be used for compressing the set of RS/channel measurements to the wireless device 1402 (not shown in the communication flow 140). In another example, the AI/ML encoder may be configured to be a sensing node proprietary model, and the server 1404 (or another node) may have the capability to develop a matching decoder (or encoder) using any cross-node AI/ML model/functionality collaboration/training techniques.

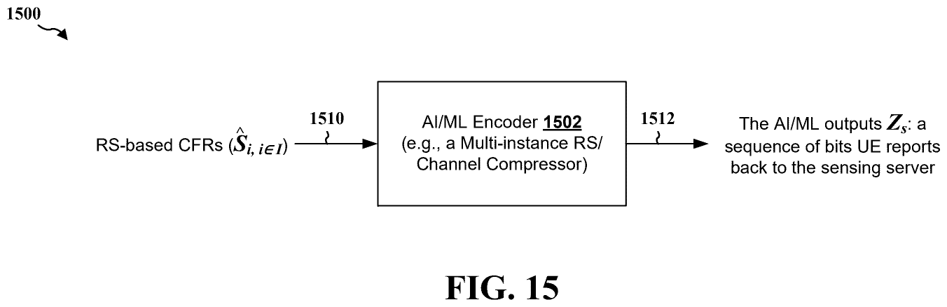

FIG. 15 is a diagram 1500 illustrating an example of AI/ML encoder in accordance with various aspects of the present disclosure. As shown at 1510, the wireless device 1402 may include an AI/ML encoder 1502 (e.g., a multi-instance RS/channel compressor) that is configured to receive a set of RS-based CFRs (represented by ŝ_{i, i∈l}) as input, and shown at 1512, the AI/ML encoder 1502 may be trained to output a sequence of bits (represented by Zs) that may be used by the wireless device 1402 for reporting back to the server 1404.

Referring back to FIG. 14. In another aspect of the present disclosure, when the wireless device 1402 measures a set of RSs to obtain the set of RS/channel measurements, the wireless device 1402 may be configured to spread the set of RS/channel measurements along subset(s) of the time domain, the frequency domain, the space (e.g., beam) domain, or a combination thereof. In other words, the wireless device 1402 may compress the set of RS/channel measurements over multiple times, multiple frequencies or frequency bandwidths, multiple spaces (e.g., a first RS from a first TRP/UE, a second RS from a second TRP/UE, etc.), or a combination thereof.

In another aspect of the present disclosure, as shown at 1414, in some implementations, the wireless device 1402 and the server 1404 may be configured to exchange capability information related to the multi-instance channel compression (performed by the wireless device 1402). In one example, the server 1404 may request the wireless device 1402 to provide capability information related to the multi-instance channel compression, and the wireless device 1402 may provide the corresponding capability information based on the request. In another example, the wireless device 1402 may be configured to indicate/provide its capability information related to the multi-instance channel compression to the server 1404 without receiving a request from the server 1404 (e.g., the wireless device 1402 is unsolicited). Depending on implementations, the capability information related to the multi-instance channel compression may include AI/ML model(s)/functionalities supported for the multi-instance channel compression, and/or AI/ML model/functionality applicability condition(s). The AI/ML model/functionality applicability condition(s) may include one or more of: (1) the maximum duration of channel measurements to be compressed, (2) the number of measurements that may be jointly compressed, (3) the feedback size as a function of the previous two properties (i.e., the operating regime), and/or (4) the compression domain(s): time, frequency, space, etc.). Based on the capability information of the wireless device 1402 related to the multi-instance channel compression, the server 1404 may transmit the configuration to compress and to report (e.g., transmit, indicate, provide, etc.) the set of RS/channel measurements to the wireless device 1402 as discussed in connection with 1410.

At 1416, after obtaining the sequence of bits (which may also be referred to as the “feedback bits”) representing the set of RS/channel measurements (e.g., using an AI/ML encoder as discussed in connection with FIG. 15), the wireless device 1402 may report (e.g., transmit, indicate, etc.) the sequence of bits to the server 1404.

At 1418, the server 1404 may construct/reconstruct the RS/channel measurements (or constructs/reconstructs the RSs/channels) using a corresponding/matching AI/ML decoder, or use the sequence of bits as an input for a processing algorithm. For example, the server 1404 may reconstruct or restore the set of RS measurements from the sequence of bits using an AI/ML decoder that corresponds or matches to the AI/ML encoder that is used by the wireless device 1402 for compressing the set of RS measurements into the sequence of bits.

In another aspect of the present disclosure, as shown at 1420, the server 1404 may transmit, to the wireless device 1402, a set of conditions for compressing and/or reporting the set of RS/channel measurements, where the wireless device 1402 may be configured to perform the compression of the set of RS/channel measurements and/or report/transmit the compression representation of the set of RS/channel measurements based on the set of conditions being met. Note while the communication flow 1400 shows the set of conditions are transmitted via a dedicated message, it is merely for illustration. The server 1404 may also include the set of conditions in other messages, such as in the configuration transmitted at 1410, or provide the set of conditions during the capability exchange at 1414, etc. Depending on implementations, the set of conditions may include: (1) a number of entries in a range-Doppler (R-D) map exceeds a signal threshold, a signal-to-noise ratio (SNR) across multiple channel instances is above an SNR threshold, or the wireless device 1402 is in a set of defined areas. In addition, the wireless device 1402 may be configured to apply a default reporting mechanism, such as reporting the R-D map(s) by default.

For example, when the number of entries above the threshold is greater than a configured value N_{max,entries}, the wireless device 1402 is configured to report a compressed representation of the measurements. However, if the number of entries above the threshold is not greater than a configured value N_{max,entries}, the wireless device 1402 is configured to report all the entries exceeding the threshold. In another example, if the minimum, average, or media SNR across multiple or all channel instances is above a defined threshold, the wireless device 1402 is configured to use a default reporting. However, if the minimum, average, or media SNR across multiple or all channel instances is below a defined threshold, the wireless device 1402 is configured to use the AI/ML compression. This is because when SNR is low, classical/conventional techniques may fail while AI/ML encoder may be able to extract fine details in the channel in those SNR-limited conditions.

In some examples, the selection of the AI/ML encoder and/or whether to apply a fallback reporting mechanism may be left up to the choice of the wireless device 1402. For example, the wireless device 1402 may have the capability to indicate the reporting method(s) in its channel feedback report. Various criteria may be defined/used for driving the selection, such as the battery level of the wireless device 1402, the computational load of the wireless device 1402, and/or the wireless channel conditions, etc.

Depending on the entity of the wireless device 1402 (e.g., whether it is a UE or a TRP) and/or the entity of the server 1404 (e.g., whether it is a sensing server, another UE, a base station, etc.), the configuration, reporting, and/or capabilities signaling may be carried out on any of the following signaling approaches: (1) for LMF-UE protocols: LTE Positioning Protocol (LPP), NR Positioning Protocol A (NRPPa); and (2) for BS/gNB-UE signaling: downlink control information (DCI), medium access control (MAC) control element (CE) (MAC-CE), radio resource control (RRC) signaling, uplink control information (UCI), sidelink (SL) signaling, etc.

In another aspect of the present disclosure, to enable more flexibility for optimized operations, the server 1404 may also include the capability to configure the wireless device 1402 with multiple encoding configurations, such that the wireless device 1402 may be configured to select one of the multiple encoding configurations to use for encoding its RS/channel measurements. In addition, the multiple encoding configurations may be configured/associated with a priority order, such that the wireless device may try to select the configuration(s) to be applied based on their priority (when possible/applicable).

In some examples, each encoding configuration may be differentiated by a set of features, such as a unique model ID, a different feedback bits size (e.g., may be the same or different models), and/or different RS configuration's, etc. For example, a single AI/ML encoder may be used, but the AI/ML encoder may have the capability to output different feedback sizes of compression bits based on a target accuracy. In another example, the wireless device 1402 may receive two RS configurations to perform two different sets of RS/channel measurements, where the first set of RS/channel measurements is done on a first set of RSs, and the second set of measurements is done on a second set of RSs (e.g., the first set of RS/channel measurement may use a first AI/ML encoder, and the second set of RS/channel measurements may use a second AI/ML encoder or without compression, etc.).

The wireless device 1402 may be configured to select one of the encoding configurations (provided/configured by the server 1404) for encoding its RS/channel measurements and feeding back (to the server 1404) the index/ID of the encoding configuration used. Similarly, the selection of the encoding configuration may be based on multiple factors, including the wireless channel conditions, the processing load of the wireless device 1402, the battery level of the wireless device 1402, etc. The wireless device 1402 may also report/transmit the selection criteria along with the measurements feedback to the server 1404. In some examples, to enable the multiple encoding configurations, the wireless device 1402 may provide/declare its corresponding capabilities to the server 1404, such as during the capability exchange discussed in connection with 1414.

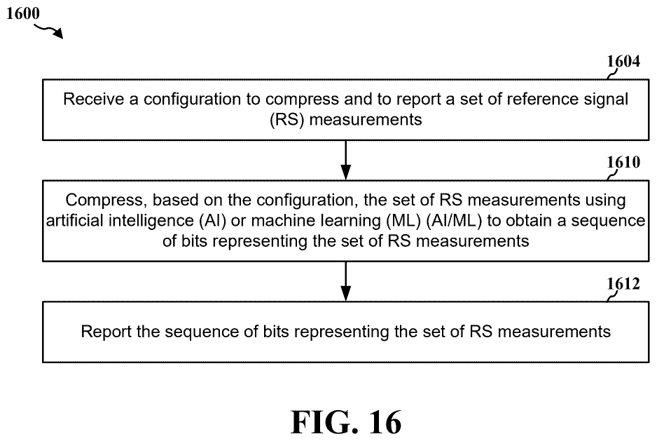

FIG. 16 is a flowchart 1600 of a method of wireless communication. The method may be performed by a wireless device (e.g., the UE 104, 404, 702; the TRP 402, 406; the wireless device 1302, 1402; the apparatus 1804). The method may enable the wireless device to provide a plurality of RS/channel measurements using an explicit feedback (e.g., using a compressed representation of the plurality of RS/channel measurements) for RF sensing and/or positioning, thereby improving the overall performance of RF sensing and/or positioning.

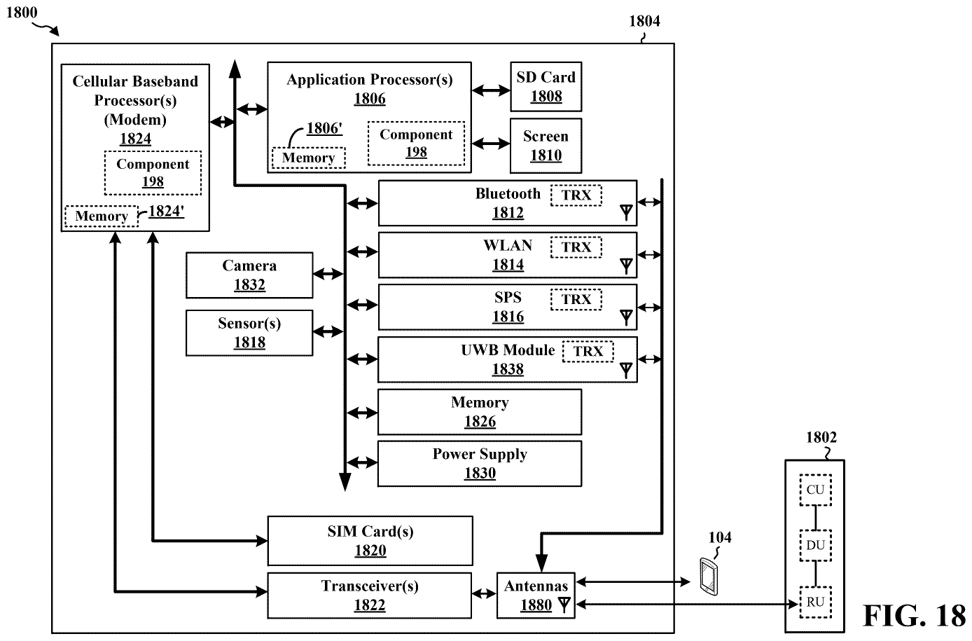

At 1604, the wireless device may receive a configuration to compress and to report a set of RS measurements, such as described in connection with FIG. 14. For example, at 1410, a server 1404 may be configured to transmit, to a wireless device 1402, an indication of a configuration to compress and to report a set of RS/channel measurements. The reception of the configuration may be performed by, e.g., the measurement compression component 198, the transceiver(s) 1822, the cellular baseband processor(s) 1824, and/or the application processor(s) 1806 of the apparatus 1804 in FIG. 18.

In one example, the set of RS measurements corresponds to a plurality of channel measurements performed on a plurality of reference signals, the wireless device may measure the plurality of reference signals to obtain the set of RS measurements.

In another example, the configuration indicates a set of pre-processing steps to be applied before compressing the set of RS measurements using the AI/ML, the wireless device may apply the set of pre-processing steps to the set of RS measurements prior to compressing the set of RS measurements using the AI/ML.

In another example, the configuration indicates at least one AI/ML model or functionality to be used for compressing the set of RS measurements.

At 1610, the wireless device may compress, based on the configuration, the set of RS measurements using AI/ML to obtain a sequence of bits representing the set of RS measurements, such as described in connection with FIGS. 14 and 15. For example, as discussed in connection with 1412 of FIG. 14, based on the configuration (i.e., received at 1410), the wireless device 1402 may be configured to compress the set of RS/channel measurements using at least one AI/ML model/functionality to obtain a sequence of bits representing the set of RS/channel measurements. The compression of the set of RS measurements may be performed by, e.g., the measurement compression component 198, the transceiver(s) 1822, the cellular baseband processor(s) 1824, and/or the application processor(s) 1806 of the apparatus 1804 in FIG. 18.

In one example, the set of RS measurements is spread along on at least one subset of at least one of a time domain, a frequency domain, or a space domain.

In another example, the configuration includes a plurality of compression configurations, and to compress, based on the configuration, the set of RS measurements, the wireless device may be configured to select a compression configuration from the plurality of compression configurations, and compress the set of RS measurements using the selected compression configuration.

In another example, the set of measurements is related to positioning or sensing.

In another example, the AI/ML includes an AI/ML model, an AI/ML encoder, or an AI/ML functionality that is capable of measuring multiple reference signals from a source.

In another example, to receive the configuration, the wireless device may be configured to receive the configuration from a base station, a server, a sensing management function, an LMF, or a UE, and to report the sequence of bits, the wireless device may be configured to transmit the sequence of bits to the base station, the server, the sensing management function, the LMF, or the UE.

In another example, the wireless device is a UE or a TRP.

At 1612, the wireless device may report the sequence of bits representing the set of RS measurements, such as described in connection with FIG. 14. For example, at 1416, after obtaining the sequence of bits representing the set of RS/channel measurements (e.g., using an AI/ML encoder), the wireless device 1402 may report (e.g., transmit, report, etc.) the sequence of bits to the server 140. The reporting of the sequence of bits may be performed by, e.g., the measurement compression component 198, the transceiver(s) 1822, the cellular baseband processor(s) 1824, and/or the application processor(s) 1806 of the apparatus 1804 in FIG. 18.

In one example, the wireless device may receive a set of conditions for compressing and reporting the set of RS measurements, where compression of the set of RS measurements and transmission of the sequence of bits are based on the set of conditions being met, such as described in connection with FIG. 14. For example, at 1420, the wireless device 1402 may receive, from the server 1404, a set of conditions for compressing and/or reporting the set of RS/channel measurements, where the wireless device 1402 may be configured to perform the compression of the set of RS/channel measurements and/or report the compression representation of the set of RS/channel measurements based on the set of conditions being met. The reception of the set of conditions may be performed by, e.g., the measurement compression component 198, the transceiver(s) 1822, the cellular baseband processor(s) 1824, and/or the application processor(s) 1806 of the apparatus 1804 in FIG. 18. In some implementations, the set of conditions includes at least one of: a number of entries in a range-Doppler map exceeds a signal threshold, an SNR across multiple channel instances is above an SNR threshold, or the wireless device is in a set of defined areas.

In another example, the wireless device may receive, from a network entity or a UE, at least one AI/ML model or functionality to be used for compressing the set of RS measurements, such as described in connection with FIG. 14. For example, along with the configuration (transmitted at 1410) or in a separated signaling, the wireless device 1402 may receive, from the server 1404, the AI/ML encoder to be used for compressing the set of RS/channel measurements. The reception of the at least one AI/ML model or functionality may be performed by, e.g., the measurement compression component 198, the transceiver(s) 1822, the cellular baseband processor(s) 1824, and/or the application processor(s) 1806 of the apparatus 1804 in FIG. 18.

In another example, the wireless device may transmit a set of capabilities of the wireless device related to a multi-instance channel compression, where reception of the configuration is based on the set of capabilities, such as described in connection with FIG. 14. For example, at 1414, in some implementations, the wireless device 1402 and the server 1404 may be configured to exchange capability information related to the multi-instance channel compression (performed by the wireless device 1402). The transmission of the set of capabilities may be performed by, e.g., the measurement compression component 198, the transceiver(s) 1822, the cellular baseband processor(s) 1824, and/or the application processor(s) 1806 of the apparatus 1804 in FIG. 18. In some implementations, the set of capabilities includes at last one of: a maximum duration of channel measurements to be compressed, a number of RS measurements to be jointly compressed, a feedback size as a function of the maximum duration of the channel measurements to be compressed or the number of RS measurements to be jointly compressed, or one or more compression domains supported.

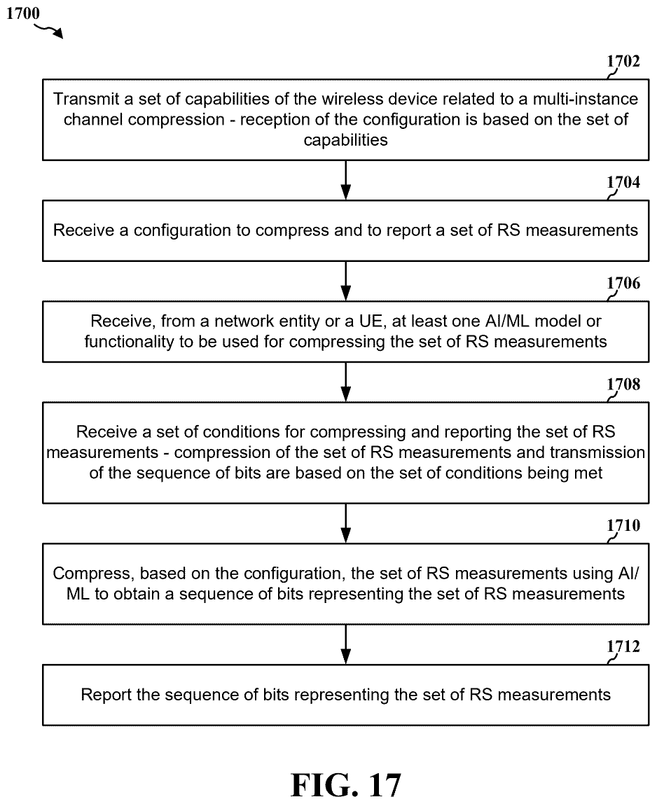

FIG. 17 is a flowchart 1700 of a method of wireless communication. The method may be performed by a wireless device (e.g., the UE 104, 404, 702; the TRP 402, 406; the wireless device 1302, 1402; the apparatus 1804). The method may enable the wireless device to provide a plurality of RS/channel measurements using an explicit feedback (e.g., using a compressed representation of the plurality of RS/channel measurements) for RF sensing and/or positioning, thereby improving the overall performance of RF sensing and/or positioning.

At 1704, the wireless device may receive a configuration to compress and to report a set of RS measurements, such as described in connection with FIG. 14. For example, at 1410, a server 1404 may be configured to transmit, to a wireless device 1402, an indication of a configuration to compress and to report a set of RS/channel measurements. The reception of the configuration may be performed by, e.g., the measurement compression component 198, the transceiver(s) 1822, the cellular baseband processor(s) 1824, and/or the application processor(s) 1806 of the apparatus 1804 in FIG. 18.

In one example, the set of RS measurements corresponds to a plurality of channel measurements performed on a plurality of reference signals, the wireless device may measure the plurality of reference signals to obtain the set of RS measurements.

In another example, the configuration indicates a set of pre-processing steps to be applied before compressing the set of RS measurements using the AI/ML, the wireless device may apply the set of pre-processing steps to the set of RS measurements prior to compressing the set of RS measurements using the AI/ML.

In another example, the configuration indicates at least one AI/ML model or functionality to be used for compressing the set of RS measurements.

At 1710, the wireless device may compress, based on the configuration, the set of RS measurements using AI/ML to obtain a sequence of bits representing the set of RS measurements, such as described in connection with FIGS. 14 and 15. For example, as discussed in connection with 1412 of FIG. 14, based on the configuration (i.e., received at 1410), the wireless device 1402 may be configured to compress the set of RS/channel measurements using at least one AI/ML model/functionality to obtain a sequence of bits representing the set of RS/channel measurements. The compression of the set of RS measurements may be performed by, e.g., the measurement compression component 198, the transceiver(s) 1822, the cellular baseband processor(s) 1824, and/or the application processor(s) 1806 of the apparatus 1804 in FIG. 18.

In one example, the set of RS measurements is spread along on at least one subset of at least one of a time domain, a frequency domain, or a space domain.

In another example, the configuration includes a plurality of compression configurations, and to compress, based on the configuration, the set of RS measurements, the wireless device may be configured to select a compression configuration from the plurality of compression configurations, and compress the set of RS measurements using the selected compression configuration.

In another example, the set of measurements is related to positioning or sensing.

In another example, the AI/ML includes an AI/ML model, an AI/ML encoder, or an AI/ML functionality that is capable of measuring multiple reference signals from a source.

In another example, to receive the configuration, the wireless device may be configured to receive the configuration from a base station, a server, a sensing management function, an LMF, or a UE, and to report the sequence of bits, the wireless device may be configured to transmit the sequence of bits to the base station, the server, the sensing management function, the LMF, or the UE.

In another example, the wireless device is a UE or a TRP.

At 1712, the wireless device may report the sequence of bits representing the set of RS measurements, such as described in connection with FIG. 14. For example, at 1416, after obtaining the sequence of bits representing the set of RS/channel measurements (e.g., using an AI/ML encoder), the wireless device 1402 may report (e.g., transmit, indicate, etc.) the sequence of bits to the server 140. The reporting of the sequence of bits may be performed by, e.g., the measurement compression component 198, the transceiver(s) 1822, the cellular baseband processor(s) 1824, and/or the application processor(s) 1806 of the apparatus 1804 in FIG. 18.

In one example, as shown at 1708, the wireless device may receive a set of conditions for compressing and reporting the set of RS measurements, where compression of the set of RS measurements and transmission of the sequence of bits are based on the set of conditions being met, such as described in connection with FIG. 14. For example, at 1420, the wireless device 1402 may receive, from the server 1404, a set of conditions for compressing and/or reporting the set of RS/channel measurements, where the wireless device 1402 may be configured to perform the compression of the set of RS/channel measurements and/or report the compression representation of the set of RS/channel measurements based on the set of conditions being met. The reception of the set of conditions may be performed by, e.g., the measurement compression component 198, the transceiver(s) 1822, the cellular baseband processor(s) 1824, and/or the application processor(s) 1806 of the apparatus 1804 in FIG. 18. In some implementations, the set of conditions includes at least one of: a number of entries in a range-Doppler map exceeds a signal threshold, an SNR across multiple channel instances is above an SNR threshold, or the wireless device is in a set of defined areas.

In another example, as shown at 1706, the wireless device may receive, from a network entity or a UE, at least one AI/ML model or functionality to be used for compressing the set of RS measurements, such as described in connection with FIG. 14. For example, along with the configuration (transmitted at 1410) or in a separated signaling, the wireless device 1402 may receive, from the server 1404, the AI/ML encoder to be used for compressing the set of RS/channel measurements. The reception of the at least one AI/ML model or functionality may be performed by, e.g., the measurement compression component 198, the transceiver(s) 1822, the cellular baseband processor(s) 1824, and/or the application processor(s) 1806 of the apparatus 1804 in FIG. 18.

In another example, as shown at 1702, the wireless device may transmit a set of capabilities of the wireless device related to a multi-instance channel compression, where reception of the configuration is based on the set of capabilities, such as described in connection with FIG. 14. For example, at 1414, in some implementations, the wireless device 1402 and the server 1404 may be configured to exchange capability information related to the multi-instance channel compression (performed by the wireless device 1402). The transmission of the set of capabilities may be performed by, e.g., the measurement compression component 198, the transceiver(s) 1822, the cellular baseband processor(s) 1824, and/or the application processor(s) 1806 of the apparatus 1804 in FIG. 18. In some implementations, the set of capabilities includes at last one of: a maximum duration of channel measurements to be compressed, a number of RS measurements to be jointly compressed, a feedback size as a function of the maximum duration of the channel measurements to be compressed or the number of RS measurements to be jointly compressed, or one or more compression domains supported.

FIG. 18 is a diagram 1800 illustrating an example of a hardware implementation for an apparatus 1804. The apparatus 1804 may be a UE, a component of a UE, or may implement UE functionality. In some aspects, the apparatus 1804 may include at least one cellular baseband processor 1824 (also referred to as a modem) coupled to one or more transceivers 1822 (e.g., cellular RF transceiver). The cellular baseband processor(s) 1824 may include at least one on-chip memory 1824′. In some aspects, the apparatus 1804 may further include one or more subscriber identity modules (SIM) cards 1820 and at least one application processor 1806 coupled to a secure digital (SD) card 1808 and a screen 1810. The application processor(s) 1806 may include on-chip memory 1806′. In some aspects, the apparatus 1804 may further include a Bluetooth module 1812, a WLAN module 1814, an ultrawide band (UWB) module 1838 (e.g., a UWB transceiver), an SPS module 1816 (e.g., GNSS module), one or more sensors 1818 (e.g., barometric pressure sensor/altimeter; motion sensor such as inertial measurement unit (IMU), gyroscope, and/or accelerometer(s); light detection and ranging (LIDAR), radio assisted detection and ranging (RADAR), sound navigation and ranging (SONAR), magnetometer, audio and/or other technologies used for positioning), additional memory modules 1826, a power supply 1830, and/or a camera 1832. The Bluetooth module 1812, the UWB module 1838, the WLAN module 1814, and the SPS module 1816 may include an on-chip transceiver (TRX) (or in some cases, just a receiver (RX)). The Bluetooth module 1812, the WLAN module 1814, and the SPS module 1816 may include their own dedicated antennas and/or utilize the antennas 1880 for communication. The cellular baseband processor(s) 1824 communicates through the transceiver(s) 1822 via one or more antennas 1880 with the UE 104 and/or with an RU associated with a network entity 1802. The cellular baseband processor(s) 1824 and the application processor(s) 1806 may each include a computer-readable medium/memory 1824′, 1806′, respectively. The additional memory modules 1826 may also be considered a computer-readable medium/memory. Each computer-readable medium/memory 1824′, 1806′, 1826 may be non-transitory. The cellular baseband processor(s) 1824 and the application processor(s) 1806 are each responsible for general processing, including the execution of software stored on the computer-readable medium/memory. The software, when executed by the cellular baseband processor(s) 1824/application processor(s) 1806, causes the cellular baseband processor(s) 1824/application processor(s) 1806 to perform the various functions described supra. The cellular baseband processor(s) 1824 and the application processor(s) 1806 are configured to perform the various functions described supra based at least in part of the information stored in the memory. That is, the cellular baseband processor(s) 1824 and the application processor(s) 1806 may be configured to perform a first subset of the various functions described supra without information stored in the memory and may be configured to perform a second subset of the various functions described supra based on the information stored in the memory. The computer-readable medium/memory may also be used for storing data that is manipulated by the cellular baseband processor(s) 1824/application processor(s) 1806 when executing software. The cellular baseband processor(s) 1824/application processor(s) 1806 may be a component of the UE 350 and may include the at least one memory 360 and/or at least one of the TX processor 368, the RX processor 356, and the controller/processor 359. In one configuration, the apparatus 1804 may be at least one processor chip (modem and/or application) and include just the cellular baseband processor(s) 1824 and/or the application processor(s) 1806, and in another configuration, the apparatus 1804 may be the entire UE (e.g., see UE 350 of FIG. 3) and include the additional modules of the apparatus 1804.

As discussed supra, the measurement compression component 198 may be configured to receive a configuration to compress and to report a set of RS measurements. The measurement compression component 198 may also be configured to compress, based on the configuration, the set of RS measurements using AI/ML to obtain a sequence of bits representing the set of RS measurements. The measurement compression component 198 may also be configured to report the sequence of bits representing the set of RS measurements. The measurement compression component 198 may be within the cellular baseband processor(s) 1824, the application processor(s) 1806, or both the cellular baseband processor(s) 1824 and the application processor(s) 1806. The measurement compression component 198 may be one or more hardware components specifically configured to carry out the stated processes/algorithm, implemented by one or more processors configured to perform the stated processes/algorithm, stored within a computer-readable medium for implementation by one or more processors, or some combination thereof. When multiple processors are implemented, the multiple processors may perform the stated processes/algorithm individually or in combination. As shown, the apparatus 1804 may include a variety of components configured for various functions. In one configuration, the apparatus 1804, and in particular the cellular baseband processor(s) 1824 and/or the application processor(s) 1806, may include means for receiving a configuration to compress and to report a set of RS measurements. The apparatus 1804 may further include means for compressing, based on the configuration, the set of RS measurements using AI/ML to obtain a sequence of bits representing the set of RS measurements. The apparatus 1804 may further include means for reporting the sequence of bits representing the set of RS measurements.

In one configuration, the set of RS measurements corresponds to a plurality of channel measurements performed on a plurality of reference signals, the apparatus 1804 may further include means for measuring the plurality of reference signals to obtain the set of RS measurements.

In another configuration, the configuration indicates a set of pre-processing steps to be applied before compressing the set of RS measurements using the AI/ML, the apparatus 1804 may further include means for applying the set of pre-processing steps to the set of RS measurements prior to compressing the set of RS measurements using the AI/ML.

In another configuration, the configuration indicates at least one AI/ML model or functionality to be used for compressing the set of RS measurements.

In another configuration, the set of RS measurements is spread along on at least one subset of at least one of a time domain, a frequency domain, or a space domain.

In another configuration, the configuration includes a plurality of compression configurations, and the means for compressing, based on the configuration, the set of RS measurements may include configuring the apparatus 1804 to select a compression configuration from the plurality of compression configurations, and compress the set of RS measurements using the selected compression configuration.

In another configuration, the set of measurements is related to positioning or sensing.

In another configuration, the AI/ML includes an AI/ML model, an AI/ML encoder, or an AI/ML functionality that is capable of measuring multiple reference signals from a source.

In another configuration, the means for receiving the configuration may include configuring the apparatus 1804 to receive the configuration from a base station, a server, a sensing management function, an LMF, or a UE, and the means for reporting the sequence of bits may include configuring the apparatus 1804 to report the sequence of bits to the base station, the server, the sensing management function, the LMF, or the UE.

In another configuration, the wireless device is a UE or a TRP.

In another configuration, the apparatus 1804 may further include means for receiving a set of conditions for compressing and reporting the set of RS measurements, where compression of the set of RS measurements and transmission of the sequence of bits are based on the set of conditions being met. In some implementations, the set of conditions includes at least one of: a number of entries in a range-Doppler map exceeds a signal threshold, an SNR across multiple channel instances is above an SNR threshold, or the wireless device is in a set of defined areas.

In another configuration, the apparatus 1804 may further include means for receiving, from a network entity or a UE, at least one AI/ML model or functionality to be used for compressing the set of RS measurements.

In another configuration, the apparatus 1804 may further include means for transmitting a set of capabilities of the wireless device related to a multi-instance channel compression, where reception of the configuration is based on the set of capabilities. In some implementations, the set of capabilities includes at last one of: a maximum duration of channel measurements to be compressed, a number of RS measurements to be jointly compressed, a feedback size as a function of the maximum duration of the channel measurements to be compressed or the number of RS measurements to be jointly compressed, or one or more compression domains supported.

The means may be the measurement compression component 198 of the apparatus 1804 configured to perform the functions recited by the means. As described supra, the apparatus 1804 may include the TX processor 368, the RX processor 356, and the controller/processor 359. As such, in one configuration, the means may be the TX processor 368, the RX processor 356, and/or the controller/processor 359 configured to perform the functions recited by the means.

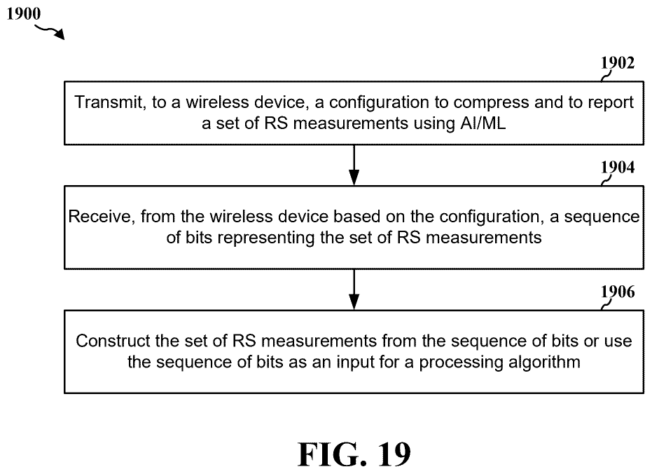

FIG. 19 is a flowchart 1900 of a method of wireless communication. The method may be performed by a server (e.g., the one or more location servers 168; the location server 704; the server 1404; the network entity 2060). The method may enable the server to configure a wireless device to provide a plurality of RS/channel measurements using an explicit feedback (e.g., using a compressed representation of the plurality of RS/channel measurements) for RF sensing and/or positioning, thereby improving the overall performance of RF sensing and/or positioning.

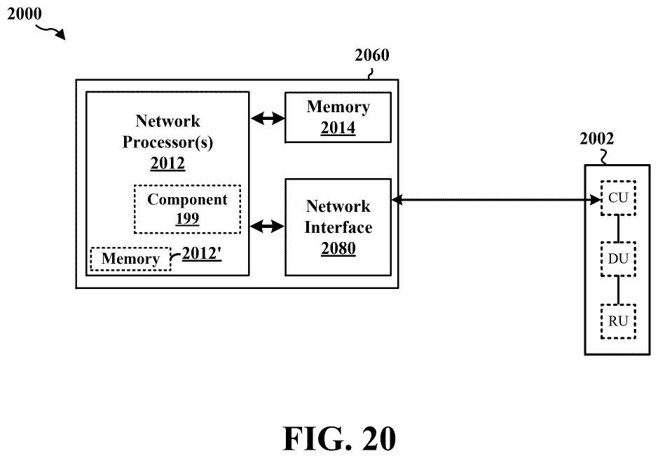

At 1902, the server may transmit, to a wireless device, a configuration to compress and to report a set of RS measurements using AI/ML, such as described in connection with FIG. 14. For example, at 1410, a server 1404 may be configured to transmit, to a wireless device 1402, an indication of a configuration to compress and to report a set of RS/channel measurements. The transmission of the configuration may be performed by, e.g., the measurement compression configuration component 199, the network processor(s) 2012, and/or the network interface 2080 of the network entity 2060 in FIG. 20.

At 1904, the server may receive, from the wireless device based on the configuration, a sequence of bits representing the set of RS measurements, such as described in connection with FIG. 14. For example, at 1416, the server may receive, from the wireless device 1402, the sequence of bits. The reception of the sequence of bits may be performed by, e.g., the measurement compression configuration component 199, the network processor(s) 2012, and/or the network interface 2080 of the network entity 2060 in FIG. 20.

At 1906, the server may construct the set of RS measurements from the sequence of bits or use the sequence of bits as an input for a processing algorithm, such as described in connection with FIG. 14. For example, at 1418, the server 1404 may construct/reconstruct the RS/channel measurements (or constructs/reconstructs the RSs/channels) using a corresponding/matching AI/ML decoder, or use the sequence of bits as an input for a processing algorithm. The construction of the set of RS measurements and/or the use of the sequence of bits as an input for a processing algorithm may be performed by, e.g., the measurement compression configuration component 199, the network processor(s) 2012, and/or the network interface 2080 of the network entity 2060 in FIG. 20.

In one example, the server may transmit, to the wireless device, a set of conditions for compressing and reporting the set of RS measurements. In some implementations, the set of conditions includes at least one of: a number of entries in a range-Doppler map exceeds a signal threshold, an SNR across multiple channel instances is above an SNR threshold, or the wireless device is in a set of defined areas.

In another example, to construct the set of RS measurements from the sequence of bits, the server may be configured to reconstruct or restore the set of RS measurements from the sequence of bits using an AI/ML decoder that corresponds or matches to an AI/ML encoder that is used for compressing the set of RS measurements into the sequence of bits.

In another example, the configuration indicates a set of pre-processing steps to be applied before compressing the set of RS measurements using the AI/ML.

In another example, the configuration indicates at least one AI/ML model or functionality to be used for compressing the set of RS measurements.

In another example, the server may transmit, to the wireless device, at least one AI/ML model or functionality to be used for compressing the set of RS measurements.

In another example, the set of RS measurements is spread along on at least one subset of at least one of a time domain, a frequency domain, or a space domain.

In another example, the server may receive, from the wireless device, a set of capabilities of the wireless device related to a multi-instance channel compression, where transmission of the configuration is based on the set of capabilities. In some implementations, the set of capabilities includes at last one of: a maximum duration of channel measurements to be compressed, a number of RS measurements to be jointly compressed, a feedback size as a function of the maximum duration of the channel measurements to be compressed or the number of RS measurements to be jointly compressed, or one or more compression domains supported.

In another example, the configuration includes a plurality of compression configurations.

In another example, the set of measurements is related to positioning or sensing.

In another example, the AI/ML includes an AI/ML model, an AI/ML encoder, or an AI/ML functionality that is capable of measuring multiple reference signals from a source.

In another example, the server is a base station, a sensing server, a sensing management function, an LMF, or a first UE, and where the wireless device is a second UE or a TRP.

FIG. 20 is a diagram 2000 illustrating an example of a hardware implementation for a network entity 2060. In one example, the network entity 2060 may be within the core network 120. The network entity 2060 may include at least one network processor 2012. The network processor(s) 2012 may include on-chip memory 2012′. In some aspects, the network entity 2060 may further include additional memory modules 2014. The network entity 2060 communicates via the network interface 2080 directly (e.g., backhaul link) or indirectly (e.g., through a RIC) with the CU 2002. The on-chip memory 2012′ and the additional memory modules 2014 may each be considered a computer-readable medium/memory. Each computer-readable medium/memory may be non-transitory. The network processor(s) 2012 is responsible for general processing, including the execution of software stored on the computer-readable medium/memory. The software, when executed by the corresponding processor(s) causes the processor(s) to perform the various functions described supra. The computer-readable medium/memory may also be used for storing data that is manipulated by the processor(s) when executing software.

As discussed supra, the measurement compression configuration component 199 may be configured to transmit, to a wireless device, a configuration to compress and to report a set of RS measurements using AI/ML. The measurement compression configuration component 199 may also be configured to receive, from the wireless device based on the configuration, a sequence of bits representing the set of RS measurements. The measurement compression configuration component 199 may also be configured to construct the set of RS measurements from the sequence of bits or use the sequence of bits as an input for a processing algorithm. The measurement compression configuration component 199 may be within the network processor(s) 2012. The measurement compression configuration component 199 may be one or more hardware components specifically configured to carry out the stated processes/algorithm, implemented by one or more processors configured to perform the stated processes/algorithm, stored within a computer-readable medium for implementation by one or more processors, or some combination thereof. When multiple processors are implemented, the multiple processors may perform the stated processes/algorithm individually or in combination. The network entity 2060 may include a variety of components configured for various functions. In one configuration, the network entity 2060 may include means for transmitting, to a wireless device, a configuration to compress and to report a set of RS measurements using AI/ML. The network entity 2060 may further include means for receiving, from the wireless device based on the configuration, a sequence of bits representing the set of RS measurements. The network entity 2060 may further include means for constructing the set of RS measurements from the sequence of bits or means for using the sequence of bits as an input for a processing algorithm.

In one configuration, the network entity 2060 may further include means for transmitting, to the wireless device, a set of conditions for compressing and reporting the set of RS measurements. In some implementations, the set of conditions includes at least one of: a number of entries in a range-Doppler map exceeds a signal threshold, an SNR across multiple channel instances is above an SNR threshold, or the wireless device is in a set of defined areas.

In another configuration, the means for constructing the set of RS measurements from the sequence of bits may include configuring the network entity 2060 to reconstruct or restore the set of RS measurements from the sequence of bits using an AI/ML decoder that corresponds or matches to an AI/ML encoder that is used for compressing the set of RS measurements into the sequence of bits.

In another configuration, the configuration indicates a set of pre-processing steps to be applied before compressing the set of RS measurements using the AI/ML.

In another configuration, the configuration indicates at least one AI/ML model or functionality to be used for compressing the set of RS measurements.

In another configuration, the network entity 2060 may further include means for transmitting, to the wireless device, at least one AI/ML model or functionality to be used for compressing the set of RS measurements.

In another configuration, the set of RS measurements is spread along on at least one subset of at least one of a time domain, a frequency domain, or a space domain.

In another configuration, the network entity 2060 may further include means for receiving, from the wireless device, a set of capabilities of the wireless device related to a multi-instance channel compression, where transmission of the configuration is based on the set of capabilities. In some implementations, the set of capabilities includes at last one of: a maximum duration of channel measurements to be compressed, a number of RS measurements to be jointly compressed, a feedback size as a function of the maximum duration of the channel measurements to be compressed or the number of RS measurements to be jointly compressed, or one or more compression domains supported.

In another configuration, the configuration includes a plurality of compression configurations.

In another configuration, the set of measurements is related to positioning or sensing.

In another configuration, the AI/ML includes an AI/ML model, an AI/ML encoder, or an AI/ML functionality that is capable of measuring multiple reference signals from a source.

In another configuration, the server is a base station, a sensing server, a sensing management function, an LMF, or a first UE, and where the wireless device is a second UE or a TRP.

The means may be the measurement compression configuration component 199 of the network entity 2060 configured to perform the functions recited by the means.

It is understood that the specific order or hierarchy of blocks in the processes/flowcharts disclosed is an illustration of example approaches. Based upon design preferences, it is understood that the specific order or hierarchy of blocks in the processes/flowcharts may be rearranged. Further, some blocks may be combined or omitted. The accompanying method claims present elements of the various blocks in a sample order, and are not limited to the specific order or hierarchy presented.

The previous description is provided to enable any person skilled in the art to practice the various aspects described herein. Various modifications to these aspects will be readily apparent to those skilled in the art, and the generic principles defined herein may be applied to other aspects. Thus, the claims are not limited to the aspects described herein, but are to be accorded the full scope consistent with the language claims. Reference to an element in the singular does not mean “one and only one” unless specifically so stated, but rather “one or more.” Terms such as “if,” “when,” and “while” do not imply an immediate temporal relationship or reaction. That is, these phrases, e.g., “when,” do not imply an immediate action in response to or during the occurrence of an action, but simply imply that if a condition is met then an action will occur, but without requiring a specific or immediate time constraint for the action to occur. The word “exemplary” is used herein to mean “serving as an example, instance, or illustration.” Any aspect described herein as “exemplary” is not necessarily to be construed as preferred or advantageous over other aspects. Unless specifically stated otherwise, the term “some” refers to one or more. Combinations such as “at least one of A, B, or C,” “one or more of A, B, or C,” “at least one of A, B, and C,” “one or more of A, B, and C,” and “A, B, C, or any combination thereof” include any combination of A, B, and/or C, and may include multiples of A, multiples of B, or multiples of C. Specifically, combinations such as “at least one of A, B, or C,” “one or more of A, B, or C,” “at least one of A, B, and C,” “one or more of A, B, and C,” and “A, B, C, or any combination thereof” may be A only, B only, C only, A and B, A and C, B and C, or A and B and C, where any such combinations may contain one or more member or members of A, B, or C. Sets should be interpreted as a set of elements where the elements number one or more. Accordingly, for a set of X, X would include one or more elements. When at least one processor (i.e., a set of one or more processors P) is configured to perform a set of functions F, each processor of P may be configured to perform a subset S of F, where S & F. Accordingly, each processor of the at least one processor may be configured to perform a particular subset of the set of functions, where the subset is the full set, a proper subset of the set, or an empty subset of the set. A processor may be referred to as processor circuitry. A memory/memory module may be referred to as memory circuitry. If a first apparatus receives data from or transmits data to a second apparatus, the data may be received/transmitted directly between the first and second apparatuses, or indirectly between the first and second apparatuses through a set of apparatuses. A device configured to “output” data or “provide” data, such as a transmission, signal, or message, may transmit the data, for example with a transceiver, or may send the data to a device that transmits the data. A device configured to “obtain” data, such as a transmission, signal, or message, may receive, for example with a transceiver, or may obtain the data from a device that receives the data. Information stored in a memory includes instructions and/or data. All structural and functional equivalents to the elements of the various aspects described throughout this disclosure that are known or later come to be known to those of ordinary skill in the art are expressly incorporated herein by reference and are encompassed by the claims. Moreover, nothing disclosed herein is dedicated to the public regardless of whether such disclosure is explicitly recited in the claims. The words “module,” “mechanism,” “element,” “device,” and the like may not be a substitute for the word “means.” As such, no claim element is to be construed as a means plus function unless the element is expressly recited using the phrase “means for.”

As used herein, the phrase “based on” shall not be construed as a reference to a closed set of information, one or more conditions, one or more factors, or the like. In other words, the phrase “based on A” (where “A” may be information, a condition, a factor, or the like) shall be construed as “based at least on A” unless specifically recited differently.

The following aspects are illustrative only and may be combined with other aspects or teachings described herein, without limitation.

Aspect 1 is a method of wireless communication at a wireless device, comprising: receiving a configuration to compress and to report a set of reference signal (RS) measurements; compressing, based on the configuration, the set of RS measurements using artificial intelligence (AI) or machine learning (ML) (AI/ML) to obtain a sequence of bits representing the set of RS measurements; and reporting the sequence of bits representing the set of RS measurements.

Aspect 2 is the method of aspect 1, further comprising: receiving a set of conditions for compressing and reporting the set of RS measurements, wherein compression of the set of RS measurements and transmission of the sequence of bits are based on the set of conditions being met.

Aspect 3 is the method of aspect 1 or aspect 2, wherein the set of conditions includes at least one of: a number of entries in a range-Doppler (R-D) map exceeds a signal threshold, a signal-to-noise ratio (SNR) across multiple channel instances is above an SNR threshold, or the wireless device is in a set of defined areas.

Aspect 4 is the method of any of aspects 1 to 3, wherein the set of RS measurements corresponds to a plurality of channel measurements performed on a plurality of reference signals, the method further comprising: measuring the plurality of reference signals to obtain the set of RS measurements.

Aspect 5 is the method of any of aspects 1 to 4, wherein the configuration indicates a set of pre-processing steps to be applied before compressing the set of RS measurements using the AI/ML, the method further comprising: applying the set of pre-processing steps to the set of RS measurements prior to compressing the set of RS measurements using the AI/ML.

Aspect 6 is the method of any of aspects 1 to 5, wherein the configuration indicates at least one AI/ML model or functionality to be used for compressing the set of RS measurements.

Aspect 7 is the method of any of aspects 1 to 6, further comprising: receiving, from a network entity or a UE, at least one AI/ML model or functionality to be used for compressing the set of RS measurements.

Aspect 8 is the method of any of aspects 1 to 7, wherein the set of RS measurements is spread along on at least one subset of at least one of a time domain, a frequency domain, or a space domain.

Aspect 9 is the method of any of aspects 1 to 8, further comprising: transmitting a set of capabilities of the wireless device related to a multi-instance channel compression, wherein reception of the configuration is based on the set of capabilities.

Aspect 10 is the method of any of aspects 1 to 9, wherein the set of capabilities includes at last one of: a maximum duration of channel measurements to be compressed, a number of RS measurements to be jointly compressed, a feedback size as a function of the maximum duration of the channel measurements to be compressed or the number of RS measurements to be jointly compressed, or one or more compression domains supported.

Aspect 11 is the method of any of aspects 1 to 10, wherein the configuration includes a plurality of compression configurations, and wherein compressing, based on the configuration, the set of RS measurements comprises: selecting a compression configuration from the plurality of compression configurations; and compressing the set of RS measurements using the selected compression configuration.

Aspect 12 is the method of any of aspects 1 to 11, wherein the set of measurements is related to positioning or sensing.

Aspect 13 is the method of any of aspects 1 to 12, wherein the AI/ML includes an AI/ML model, an AI/ML encoder, or an AI/ML functionality that is capable of measuring multiple reference signals from a source.

Aspect 14 is the method of any of aspects 1 to 13, wherein receiving the configuration comprises receiving the configuration from a base station, a server, a sensing management function, a location management function (LMF), or a user equipment (UE), and wherein reporting the sequence of bits comprises transmitting the sequence of bits to the base station, the server, the sensing management function, the LMF, or the UE.

Aspect 15 is the method of any of aspects 1 to 14, wherein the wireless device is a user equipment (UE) or a transmission reception point (TRP).

Aspect 16 is an apparatus for wireless communication at a wireless device, including: at least one memory; and at least one processor coupled to the at least one memory and, based at least in part on stored information that is stored in the at least one memory, the at least one processor, individually or in any combination, is configured to implement any of aspects 1 to 15.

Aspect 17 is the apparatus of aspect 16, further including at least one transceiver or at least one network interface coupled to the at least one processor.

Aspect 18 is an apparatus for wireless communication at a wireless device including means for implementing any of aspects 1 to 15.

Aspect 19 is a computer-readable medium (e.g., a non-transitory computer-readable medium) storing computer executable code, where the code when executed by a processor causes the processor to implement any of aspects 1 to 15.

Aspect 20 is a method of wireless communication at a server, comprising: transmitting, to a wireless device, a configuration to compress and to report a set of reference signal (RS) measurements using artificial intelligence (AI) or machine learning (ML) (AI/ML); receiving, from the wireless device based on the configuration, a sequence of bits representing the set of RS measurements; and constructing the set of RS measurements from the sequence of bits or using the sequence of bits as an input for a processing algorithm.

Aspect 21 is the method of aspect 20, further comprising: transmitting, to the wireless device, a set of conditions for compressing and reporting the set of RS measurements.

Aspect 22 is the method of aspect 20 or aspect 21, wherein the set of conditions includes at least one of: a number of entries in a range-Doppler (R-D) map exceeds a signal threshold, a signal-to-noise ratio (SNR) across multiple channel instances is above an SNR threshold, or the wireless device is in a set of defined areas.

Aspect 23 is the method of any of aspects 20 to 22, wherein constructing the set of RS measurements from the sequence of bits comprises: reconstructing or restoring the set of RS measurements from the sequence of bits using an AI/ML decoder that corresponds or matches to an AI/ML encoder that is used for compressing the set of RS measurements into the sequence of bits.

Aspect 24 is the method of any of aspects 20 to 23, wherein the configuration indicates a set of pre-processing steps to be applied before compressing the set of RS measurements using the AI/ML.

Aspect 25 is the method of any of aspects 20 to 24, wherein the configuration indicates at least one AI/ML model or functionality to be used for compressing the set of RS measurements.

Aspect 26 is the method of any of aspects 20 to 25, further comprising: transmitting, to the wireless device, at least one AI/ML model or functionality to be used for compressing the set of RS measurements.

Aspect 27 is the method of any of aspects 20 to 26, wherein the set of RS measurements is spread along on at least one subset of at least one of a time domain, a frequency domain, or a space domain.

Aspect 28 is the method of any of aspects 20 to 27, further comprising: receiving, from the wireless device, a set of capabilities of the wireless device related to a multi-instance channel compression, wherein transmission of the configuration is based on the set of capabilities.

Aspect 29 is the method of any of aspects 20 to 28, wherein the set of capabilities includes at last one of: a maximum duration of channel measurements to be compressed, a number of RS measurements to be jointly compressed, a feedback size as a function of the maximum duration of the channel measurements to be compressed or the number of RS measurements to be jointly compressed, or one or more compression domains supported.

Aspect 30 is the method of any of aspects 20 to 29, wherein the configuration includes a plurality of compression configurations.

Aspect 31 is the method of any of aspects 20 to 30, wherein the set of measurements is related to positioning or sensing.

Aspect 32 is the method of any of aspects 20 to 31, wherein the AI/ML includes an AI/ML model, an AI/ML encoder, or an AI/ML functionality that is capable of measuring multiple reference signals from a source.

Aspect 33 is the method of any of aspects 20 to 32, wherein the server is a base station, a sensing server, a sensing management function, a location management function (LMF), or a first user equipment (UE), and wherein the wireless device is a second UE or a transmission reception point (TRP).

Aspect 34 is an apparatus for wireless communication at a server, including: at least one memory; and at least one processor coupled to the at least one memory and, based at least in part on stored information that is stored in the at least one memory, the at least one processor, individually or in any combination, is configured to implement any of aspects 20 to 33.

Aspect 35 is the apparatus of aspect 34, further including at least one network interface coupled to the at least one processor.

Aspect 36 is an apparatus for wireless communication at a server including means for implementing any of aspects 20 to 33.

Aspect 37 is a computer-readable medium (e.g., a non-transitory computer-readable medium) storing computer executable code, where the code when executed by a processor causes the processor to implement any of aspects 20 to 33.

What is claimed is:

1. An apparatus for wireless communication at a wireless device, comprising:
at least one memory; and
at least one processor coupled to the at least one memory, wherein the at least one processor is configured to:
receive a configuration to compress and to report a set of reference signal (RS) measurements;
compress, based on the configuration, the set of RS measurements using artificial intelligence (AI) or machine learning (ML) (AI/ML) to obtain a sequence of bits representing the set of RS measurements; and
report the sequence of bits representing the set of RS measurements.

2. The apparatus of claim 1, wherein the at least one processor is further configured to:
receive a set of conditions for compressing and reporting the set of RS measurements, wherein compression of the set of RS measurements and transmission of the sequence of bits are based on the set of conditions being met.

3. The apparatus of claim 2, wherein the set of conditions includes at least one of:
a number of entries in a range-Doppler (R-D) map exceeds a signal threshold,
a signal-to-noise ratio (SNR) across multiple channel instances is above an SNR threshold, or
the wireless device is in a set of defined areas.

4. The apparatus of claim 1, wherein the set of RS measurements corresponds to a plurality of channel measurements performed on a plurality of reference signals, wherein the at least one processor is further configured to:
measure the plurality of reference signals to obtain the set of RS measurements.

5. The apparatus of claim 1, wherein the configuration indicates a set of pre-processing steps to be applied before compressing the set of RS measurements using the AI/ML, wherein the at least one processor is further configured to:
apply the set of pre-processing steps to the set of RS measurements prior to compressing the set of RS measurements using the AI/ML.

6. The apparatus of claim 1, wherein the configuration indicates at least one AI/ML model or functionality to be used for compressing the set of RS measurements.

7. The apparatus of claim 1, wherein the at least one processor is further configured to:
receive, from a network entity or a UE, at least one AI/ML model or functionality to be used for compressing the set of RS measurements.

8. The apparatus of claim 1, wherein the set of RS measurements is spread along on at least one subset of at least one of a time domain, a frequency domain, or a space domain.

9. The apparatus of claim 1, wherein the at least one processor is further configured to:
transmit a set of capabilities of the wireless device related to a multi-instance channel compression, wherein reception of the configuration is based on the set of capabilities.

10. The apparatus of claim 9, wherein the set of capabilities includes at last one of:
a maximum duration of channel measurements to be compressed,
a number of RS measurements to be jointly compressed,
a feedback size as a function of the maximum duration of the channel measurements to be compressed or the number of RS measurements to be jointly compressed, or
one or more compression domains supported.

11. The apparatus of claim 1, wherein the configuration includes a plurality of compression configurations, and wherein to compress, based on the configuration, the set of RS measurements, the at least one processor is configured to:
select a compression configuration from the plurality of compression configurations; and
compress the set of RS measurements using the selected compression configuration.

12. The apparatus of claim 1, wherein the set of measurements is related to positioning or sensing.

13. The apparatus of claim 1, wherein the AI/ML includes an AI/ML model, an AI/ML encoder, or an AI/ML functionality that is capable of measuring multiple reference signals from a source.

14. The apparatus of claim 1, wherein to receive the configuration, the at least one processor is configured to receive the configuration from a base station, a server, a sensing management function, a location management function (LMF), or a user equipment (UE), and wherein to report the sequence of bits, the at least one processor is configured to transmit the sequence of bits to the base station, the server, the sensing management function, the LMF, or the UE.

15. The apparatus of claim 1, wherein the wireless device is a user equipment (UE) or a transmission reception point (TRP).

16. A method of wireless communication at a wireless device, comprising:
receiving a configuration to compress and to report a set of reference signal (RS) measurements;
compressing, based on the configuration, the set of RS measurements using artificial intelligence (AI) or machine learning (ML) (AI/ML) to obtain a sequence of bits representing the set of RS measurements; and
reporting the sequence of bits representing the set of RS measurements.

17. An apparatus for wireless communication at a server, comprising:
at least one memory; and
at least one processor coupled to the at least one memory, wherein the at least one processor is configured to:
transmit, to a wireless device, a configuration to compress and to report a set of reference signal (RS) measurements using artificial intelligence (AI) or machine learning (ML) (AI/ML);
receive, from the wireless device based on the configuration, a sequence of bits representing the set of RS measurements; and
construct the set of RS measurements from the sequence of bits or use the sequence of bits as an input for a processing algorithm.

18. The apparatus of claim 17, wherein the at least one processor is further configured to:
transmit, to the wireless device, a set of conditions for compressing and reporting the set of RS measurements.

19. The apparatus of claim 18, wherein the set of conditions includes at least one of:
a number of entries in a range-Doppler (R-D) map exceeds a signal threshold,
a signal-to-noise ratio (SNR) across multiple channel instances is above an SNR threshold, or
the wireless device is in a set of defined areas.

20. The apparatus of claim 17, wherein to construct the set of RS measurements from the sequence of bits, the at least one processor is configured to:
reconstruct or restore the set of RS measurements from the sequence of bits using an AI/ML decoder that corresponds or matches to an AI/ML encoder that is used for compressing the set of RS measurements into the sequence of bits.

21. The apparatus of claim 17, wherein the configuration indicates a set of pre-processing steps to be applied before compressing the set of RS measurements using the AI/ML.

22. The apparatus of claim 17, wherein the configuration indicates at least one AI/ML model or functionality to be used for compressing the set of RS measurements.

23. The apparatus of claim 17, wherein the at least one processor is further configured to:
transmit, to the wireless device, at least one AI/ML model or functionality to be used for compressing the set of RS measurements.

24. The apparatus of claim 17, wherein the set of RS measurements is spread along on at least one subset of at least one of a time domain, a frequency domain, or a space domain.

25. The apparatus of claim 17, wherein the at least one processor is further configured to:
receive, from the wireless device, a set of capabilities of the wireless device related to a multi-instance channel compression, wherein transmission of the configuration is based on the set of capabilities.

26. The apparatus of claim 25, wherein the set of capabilities includes at last one of:
a maximum duration of channel measurements to be compressed,
a number of RS measurements to be jointly compressed,
a feedback size as a function of the maximum duration of the channel measurements to be compressed or the number of RS measurements to be jointly compressed, or
one or more compression domains supported.

27. The apparatus of claim 17, wherein the configuration includes a plurality of compression configurations.

28. The apparatus of claim 17, wherein the set of measurements is related to positioning or sensing, and wherein the AI/ML includes an AI/ML model, an AI/ML encoder, or an AI/ML functionality that is capable of measuring multiple reference signals from a source.

29. The apparatus of claim 17, wherein the server is a base station, a sensing server, a sensing management function, a location management function (LMF), or a first user equipment (UE), and wherein the wireless device is a second UE or a transmission reception point (TRP).

30. A method of wireless communication at a server, comprising:
transmitting, to a wireless device, a configuration to compress and to report a set of reference signal (RS) measurements using artificial intelligence (AI) or machine learning (ML) (AI/ML);
receiving, from the wireless device based on the configuration, a sequence of bits representing the set of RS measurements; and
constructing the set of RS measurements from the sequence of bits or using the sequence of bits as an input for a processing algorithm.
